(19) United States
(12) Patent Application Publication
(10) Pub. No.: US 2025/0244387 A1
(43) Pub. Date: Jul. 31, 2025

(54) METHOD AND APPARATUS WITH BATTERY STATE ESTIMATION

(71) Applicant: Samsung Electronics Co., Ltd., Suwon-si (KR)

(72) Inventor: Jinho KIM, Suwon-si (KR)

(73) Assignee: Samsung Electronics Co., Ltd., Suwon-si (KR)

(21) Appl. No.: 18/973,818

(22) Filed: Dec. 9, 2024

(30) Foreign Application Priority Data
Jan. 31, 2024 (KR) 10-2024-0015079

(51) Int. Cl. G01R 31/36; G01R 31/367; G01R 31/388; G01R 31/392

(52) U.S. Cl. CPC G01R 31/3648; G01R 31/367; G01R 31/388; G01R 31/392

(57) ABSTRACT

A processor-implemented method including determining a voltage difference between an estimated voltage of a battery determined through a battery model and a sensed voltage of the battery, determining a state of charge (SOC) error amount based on the determined voltage difference, determining a first cumulative SOC compensation amount, the first cumulative SOC compensation amount being accumulated SOC compensation amounts used to compensate an SOC of the battery at a partially discharged point in time of the battery, estimating a second cumulative SOC compensation amount at a fully discharged point in time of the battery based on the determined first cumulative SOC compensation amount and a predetermined SOC compensation amount prediction curve, adjusting the estimated second cumulative SOC compensation amount based on the determined SOC error amount, and updating an aging parameter of the battery model based on the adjusted second cumulative SOC compensation amount.

### CROSS-REFERENCE TO RELATED APPLICATIONS

This application claims the benefit under 35 USC § 119 (a) of Korean Patent Application No. 10-2024-0015079, filed on Jan. 31, 2024, in the Korean Intellectual Property Office, the entire disclosure of which is incorporated herein by reference for all purposes.

### BACKGROUND

### 1. Field

The following description relates to a method and apparatus with battery state estimation.

### 2. Description of Related Art

There are various ways to estimate the state of a battery. For example, a battery's state may typically be estimated by integrating currents of the batteries or by using a battery model (for example, an electric circuit model or an electrochemical model).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including determining a voltage difference between an estimated voltage of a battery determined through a battery model and a sensed voltage of the battery, determining a state of charge (SOC) error amount based on the determined voltage difference, determining a first cumulative SOC compensation amount, the first cumulative SOC compensation amount being accumulated SOC compensation amounts used to compensate an SOC of the battery at a partially discharged point in time of the battery, estimating a second cumulative SOC compensation amount at a fully discharged point in time of the battery based on the determined first cumulative SOC compensation amount and a predetermined SOC compensation amount prediction curve, adjusting the estimated second cumulative SOC compensation amount based on the determined SOC error amount, and updating an aging parameter of the battery model based on the adjusted second cumulative SOC compensation amount.

The adjusting of the estimated second cumulative SOC compensation amount may include adjusting the estimated second cumulative SOC compensation amount by subtracting the determined SOC error amount from the estimated second cumulative SOC compensation amount or adding the estimated second cumulative SOC compensation amount to the determined SOC error amount.

The determining of the voltage difference may include determining whether a start condition for determining the SOC error amount is satisfied and, in response to determining that the start condition is satisfied, determining the voltage difference.

The determining whether the start condition is satisfied may include determining that the start condition is satisfied in response to an anode concentration of the battery reaching a predetermined concentration value or the SOC of the battery reaching a predetermined SOC value.

The estimating of the second cumulative SOC compensation amount may include obtaining a third cumulative SOC compensation amount corresponding to a partially discharged battery state at the partially discharged point in time in the SOC compensation amount prediction curve, obtaining a fourth cumulative SOC compensation amount corresponding to a fully discharged battery state at the fully discharged point in time in the SOC compensation amount prediction curve, and estimating the second cumulative SOC compensation amount using the determined first cumulative SOC compensation amount, the obtained third cumulative SOC compensation amount, and the obtained fourth cumulative SOC compensation amount.

The determining of the SOC error amount may include obtaining an open circuit voltage (OCV) corresponding to the SOC of the battery determined by the battery model in an OCV table and determining the SOC error amount by reflecting the determined voltage difference in the obtained OCV.

The determining of the SOC error amount may include determining a first open circuit potential (OCP) of each electrode of plural electrodes of the battery using a surface concentration of each of the electrodes, determining a first OCV of the battery using each determined first OCP, compensating each determined surface concentration based on an initial SOC error amount,

determining a second OCP of the each electrode of the plural electrodes using each compensated surface concentration, determining a second OCV of the battery using each determined second OCP, and determining the SOC error amount using the determined first OCV, the determined second OCV, the initial SOC error amount, and the determined voltage difference.

The updating of the aging parameter may include storing aging parameter values calculated based on the adjusted second cumulative SOC compensation amount in a memory, and in response to an update condition for the aging parameter being satisfied, updating the aging parameter using one or more aging parameter values stored in the memory.

The updating of the aging parameter may include storing the adjusted second cumulative SOC compensation amount in a memory, in response to an update condition for the aging parameter being satisfied, calculating an average value of a plurality of adjusted second cumulative SOC compensation amounts stored in the memory, and updating the aging parameter using the calculated average value.

The aging parameter may be an electrode balance shift.

In a general aspect, here is provided a processor-implemented method including determining a state of charge (SOC) error amount based on a determined voltage difference between an estimated voltage of a battery determined through a battery model and a sensed voltage of the battery, estimating a second cumulative SOC compensation amount at a fully discharged point in time of the battery based on a first cumulative SOC compensation amount, the first cumulative SOC compensation amount being accumulated SOC compensation amounts used to compensate an SOC of the battery at a partially discharged point in time of the battery, and a predetermined SOC compensation amount prediction curve, and updating an aging parameter of the battery model based adjusting the estimated second cumulative SOC compensation amount based on the determined SOC error amount.

In a general aspect, here is provided an electronic device including a processor configured to execute instructions and a memory storing the instructions and a battery model, and an execution of the instructions configures the processor to determine a voltage difference between an estimated voltage of a battery determined through the battery model and a sensed voltage of the battery, determine a state of charge (SOC) error amount based on the determined voltage difference, determine a first cumulative SOC compensation amount, the first cumulative SOC compensation amount being accumulated SOC compensation amounts used to compensate an SOC of the battery at a partially discharged point in time of the battery, estimate a second cumulative SOC compensation amount at a fully discharged point in time of the battery based on the determined first cumulative SOC compensation amount and a predetermined SOC compensation amount prediction curve, adjust the estimated second cumulative SOC compensation amount based on the determined SOC error amount, and update an aging parameter of the battery model based on the adjusted second cumulative SOC compensation amount.

The processor may be further configured to adjust the estimated second cumulative SOC compensation amount by subtracting the determined SOC error amount from the estimated second cumulative SOC compensation amount or adding the estimated second cumulative SOC compensation amount to the determined SOC error amount.

The processor may be further configured to determine whether a start condition for determining the SOC error amount is satisfied, and, in response to determining that the start condition is satisfied, determine the voltage difference.

The processor may be further configured to determine that the start condition is satisfied in response to an anode concentration of the battery reaching a predetermined concentration value or the SOC of the battery reaching a predetermined SOC value.

The processor may be further configured to obtain a third cumulative SOC compensation amount corresponding to a particularly discharged battery state at the partially discharged point in time in the SOC compensation amount prediction curve, obtain a fourth cumulative SOC compensation amount corresponding to a fully discharged battery state at the fully discharged point in time in the SOC compensation amount prediction curve, and estimate the second cumulative SOC compensation amount using the determined first cumulative SOC compensation amount, the obtained third cumulative SOC compensation amount, and the obtained fourth cumulative SOC compensation amount.

The processor may be further configured to obtain an open circuit voltage (OCV) corresponding to the SOC of the battery determined by the battery model in an OCV table and determine the SOC error amount by reflecting the determined voltage difference in the obtained OCV.

The processor may be further configured to determine a first open circuit potential (OCP) of each electrode of plural electrodes of the battery using a surface concentration of each of the electrodes, determine a first OCV of the battery using each determined first OCP,
compensate each determined surface concentration based on an initial SOC error amount,
determine a second OCP of the each electrode of the plural electrodes using each compensated surface concentration, determine a second OCV of the battery using each determined second OCP, and determine the SOC error amount using the determined first OCV, the determined second OCV, the initial SOC error amount, and the determined voltage difference.

The processor may be further configured to store aging parameter values calculated based on the adjusted second cumulative SOC compensation amount in the memory, and, in response to an update condition for the aging parameter being satisfied, update the aging parameter using one or more aging parameter values stored in the memory.

The processor may be further configured to store the adjusted second cumulative SOC compensation amount in the memory, in response to an update condition for the aging parameter being satisfied, calculate an average value of a plurality of adjusted second cumulative SOC compensation amounts stored in the memory, and update the aging parameter using the calculated average value.

Other features and aspects will be apparent from the following detailed description, the drawings, and the claims.

### BRIEF DESCRIPTION OF THE DRAWINGS

FIG. 1 illustrates an example battery system according to one or more embodiments.

FIG. 2 illustrates an example electrochemical model according to one or more embodiments.

FIG. 3 illustrates an example process of operating a compensator according to one or more embodiments.

FIG. 4 illustrates an example compensator according to one or more embodiments.

FIG. 5 illustrates an example process of operating a compensator according to one or more embodiments.

FIG. 6 illustrates example processes of determining a state of charge (SOC) compensation amount prediction curve according to one or more embodiments.

FIG. 7 illustrates example processes of estimating a cumulative SOC compensation amount according to one or more embodiments.

FIGS. 8 and 9 illustrate example processes of determining an SOC compensation amount prediction curve according to one or more embodiments.

FIG. 10 illustrates an example of a voltage difference according to one or more embodiments.

FIG. 11 illustrates an example method of estimating a battery state according to one or more embodiments.

FIGS. 12 and 13 illustrate example processes of determining an SOC error amount by a battery state estimation apparatus according to one or more embodiments.

FIGS. 14 and 15 illustrate example processes of determining an SOC error amount by a battery state estimation apparatus according to one or more embodiments.

FIG. 16 illustrates an example method of updating an aging parameter according to one or more embodiments.

FIG. 17 illustrates an example an electronic apparatus according to one or more embodiments.

FIG. 18 illustrates an example electronic device including a battery state estimation apparatus according to one or more embodiments.

FIG. 19 illustrates an example mobile device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

It may be typically difficult to estimate some aging parameters in an actual battery usage environment, where a user of the device may have a unique operating pattern that may affect the aging of the battery. For example, an electrode balance shift, which is an aging parameter, may be estimated at a low SOC or anode stoichiometric concentration at a fully discharged point in time, and a corresponding estimation condition may not be easily achieved according to an actual battery use pattern of the user. Accordingly, there is a desire to accurately estimate the electrode balance shift at a partially discharged point in time, the partially discharged point in time being before the fully discharged point in time is reached.

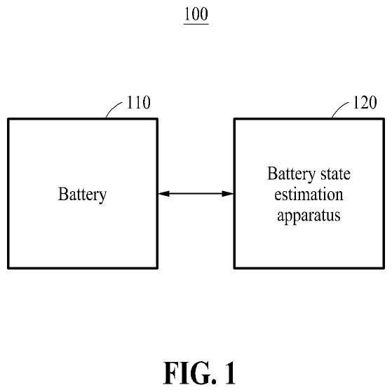

FIG. 1 illustrates an example battery system according to one or more embodiments.

Referring to FIG. 1, in a non-limiting example, a battery system 100 may include a battery 110 and a battery state estimation apparatus 120.

The battery 110 may be one or more battery cells, battery modules, or battery packs, and may be a rechargeable battery.

In an example, the battery state estimation apparatus 120 may be an apparatus for estimating a battery state for optimal management of the battery 110 and include, in an example, a battery management system (BMS). The battery state estimation apparatus 120 may sense the battery 110 using one or more sensors (e.g., at least one of a voltage sensor, a current sensor, or a temperature sensor). In other words, the battery state estimation apparatus 120 collects sensing data obtained by sensing the battery 110. In an example, the sensing data may include any one or any combination of voltage data, current data, and temperature data. In an example, the battery state estimation apparatus 120 may measure measurement data for the battery, including any one or more of measured voltage data, current data, and temperature data. However, the sensing or measurement of the battery is not limited thereto.

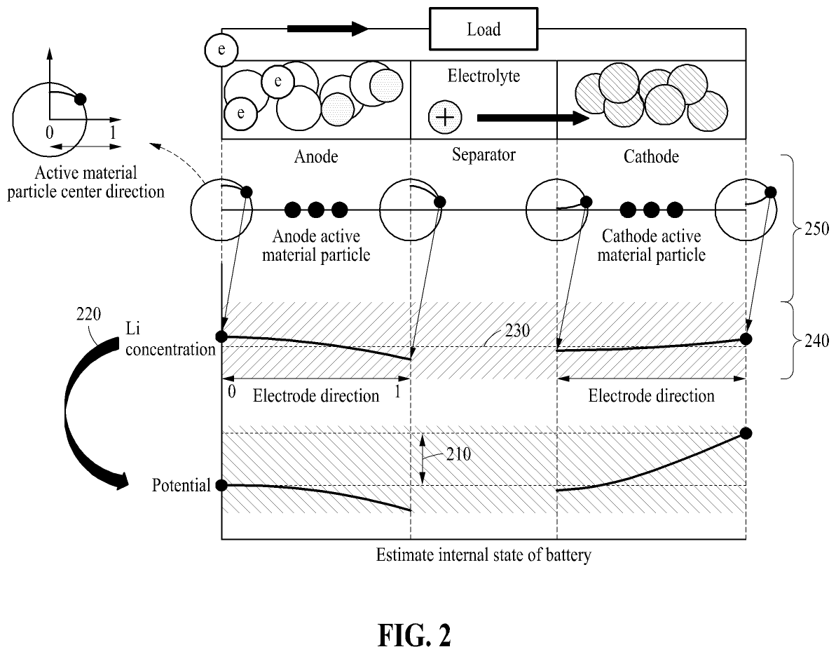

The battery state estimation apparatus 120 may estimate (i.e., calculate or determine) state information of the battery 110 based on the sensing data and output the estimated state information. The state information may include, for example, any one or any combination of a state of charge (SOC), a relative state of charge (RSOC), a state of health (SOH), and abnormality state information. A battery model used to estimate the state information may be an electrochemical model. The electrochemical model will be described in greater detail below with reference to FIG. 2.

Since the available region of the battery 110 may expand according to the accuracy of estimating the state information of the battery 110, estimating accurate state information of the battery 110 may be relevant to the operation of the battery state estimation apparatus 120. The battery state estimation apparatus 120 may reflect in the battery model an accurate aged state of the battery 110, thereby estimating state information reflecting the aged state of the battery 110 at high accuracy.

There are various aging factors of the battery 110, such as an increase in simple resistance component, a decrease in amount of cathode or anode active material, and an occurrence of lithium (Li) plating. The aspect of aging may vary depending on a use pattern of a user who uses the battery, and a usage environment. In particular, aging characteristics of the battery 110 may vary depending on the use form of the user who uses the battery and the environment. In an example, even when the battery 110 has the same reduction in the capacity due to aging, the internal state of the aged battery 110 may be different. In order to accurately reflect aging in the battery model, aging parameters of the battery 110 estimated through an analysis of response characteristics (e.g., voltage, etc.) of the battery aged depending on a user may be updated to the battery model. The accuracy of the state information of the battery 110 estimated by the battery state estimation apparatus 120 may be a relevant element in the optimal management and control of the battery 110.

FIG. 2 illustrates an example electrochemical model according to one or more embodiments.

Referring to FIG. 2, in a non-limiting example, an electrochemical model may estimate a residual capacity of a battery by modeling internal physical phenomena of the battery 110, such as an ion concentration, a potential, and the like of the battery 110. In other words, the electrochemical model may be represented by a physical conservation equation associated with an electrochemical reaction occurring on an electrode/electrolyte interface, an electrode/electrolyte concentration, and the conservation of electrical charges. For this, various model parameters such as a shape (e.g., a thickness, a radius, etc.), an open circuit potential (OCP), and a physical property value (e.g., electrical conductance, ionic conductance, diffusion coefficient, etc.) are used.

In the electrochemical model, different state variables, such as a concentration and a potential, may be coupled to one another. An estimated voltage 210 of the battery 110 estimated by the electrochemical model may be a difference in the potential between both ends which are a cathode and an anode. As indicated by an arrow 220, information regarding the potential for the cathode and the anode may be affected by the ion concentration distribution of each of the cathode and the anode. An SOC 230 estimated by the electrochemical model may correspond to an average ion concentration of the cathode and the anode.

Here, the ion concentration distribution may be an ion concentration distribution 240 in an electrode or an ion concentration distribution 250 in an active material particle present at a predetermined position in the electrode. The ion concentration distribution 240 in the electrode may be a surface ion concentration distribution or an average ion concentration distribution of an active material particle positioned in an electrode direction, and the electrode direction may be a direction connecting one end of the electrode (e.g., a boundary adjacent to a collector) and the other end of the electrode (e.g., a boundary adjacent to a separator). In addition, the ion concentration distribution 250 in the active material particle may be an ion concentration distribution within the active material particle according to a center direction of the active material particle, and the center direction of the active material particle may be a direction connecting the center of the active material particle and the surface of the active material particle.

To reduce a voltage difference dV between a measured voltage (or a sensed voltage) and an estimated voltage of the battery 110 (e.g., sensed voltage-estimated voltage), the ion concentration distribution of the cathode and the anode may be moved while maintaining the physical conservation associated with concentration, the information regarding the potential of each of the cathode and the anode may be derived based on the moved concentration distribution, and the voltage may be calculated based on the derived information regarding the potential of each of the cathode and the anode. A current SOC of the battery may be finally determined by deriving an internal state movement amount that makes the voltage difference dV be “0”.

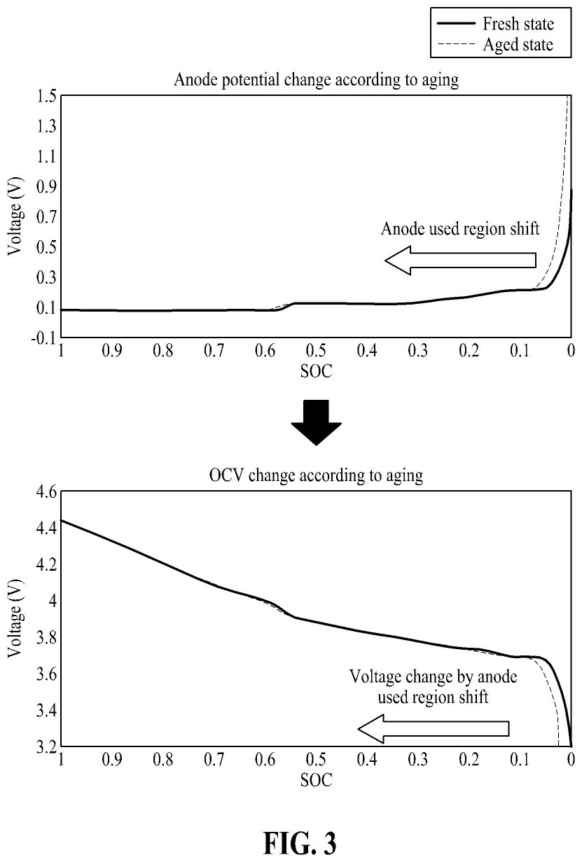

FIG. 3 illustrates an example process of operating a compensator according to one or more embodiments.

Referring to FIG. 3, in a non-limiting example, anode potentials (e.g., OCPs) and cell voltages (e.g., open circuit voltages (OCVs)) in a fresh state in which a battery is not aged and in an aged state in which the battery is aged are illustrated.

The electrode balance shift is a characteristic that a used region of the anode is moved at a cathode-anode potential difference which determines the voltage of the battery, which may cause a change in the OCV characteristic of the battery, which may be due to a change in the anode potential.

In other words, the cathode potential may show a slight difference between the fresh state and the aged state, whereas the anode potential may have a great difference between the fresh state and the aged state at a low SOC. The anode potential in the aged state may be in a shape that is shifted leftward from the anode potential in the fresh state, which may be referred to as an “electrode balance shift.”

A cell voltage graph indicates that a battery is used and discharged. A difference between a voltage in the fresh state and a voltage in the aged state may be larger at a low SOC at the end of discharging than at a high SOC at the beginning of discharging. In particular, at a low SOC, a drastic change in the voltage difference between the fresh state and the aged state may occur. The cause may be found in the electrode balance shift.

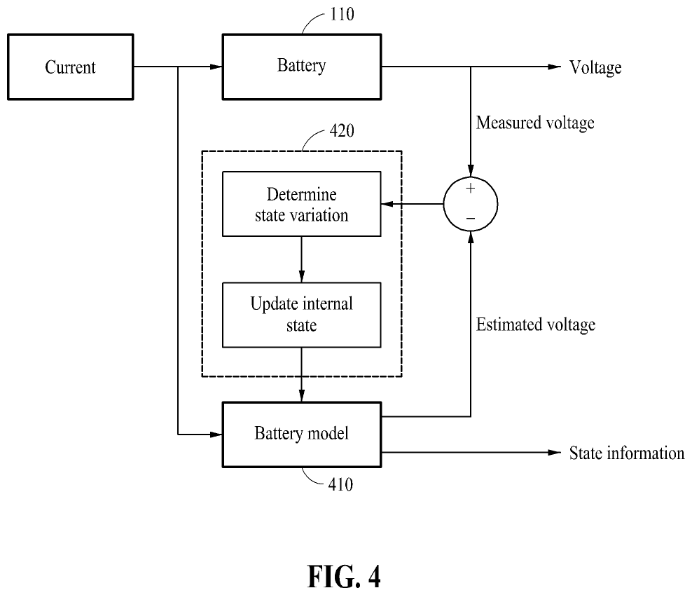

When the battery model does not reflect the current aged state well because the actual battery is aged by its own electrode balance shift, the cell voltage graphs of the fresh state and the aged state shown in FIG. 3 may not reflect the current aged state of the battery, such as the actual measured voltage, properly. A difference between the estimated voltage of the electrochemical model and the actual measured voltage of the battery may be reduced by a compensator, and an operation of the compensator will be described in greater detail below with reference to FIG. 4.

FIG. 4 illustrates an example compensator according to one or more embodiments.

Referring to FIG. 4, in a non-limiting example, a compensator 420 may compensate an internal state of a battery model 410 (e.g., an electrochemical model) when a voltage difference (or an error) between a measured voltage and an estimated voltage of the battery 110 estimated by the battery model 410 (e.g., an electrochemical model) occurs.

The battery state estimation apparatus 120 may determine (e.g., calculate or estimate) state information of the battery 110 using the battery model 410. In an example, battery model 410 may be a model that estimates state information of the battery 110 by modeling an internal physical phenomenon, such as a potential or an ion concentration distribution, of the battery 110.

The accuracy of estimating the state information of the battery 110 may affect the optimal management and control of the battery 110. When the state information is estimated using the battery model 410, an error may occur between values from sensor information obtained by measuring current, voltage, and temperature data to be input into the battery model 410 and values of state information calculated using a modeling scheme. In an example, the compensator 420 may compensate for this error when it occurs.

First, a voltage difference between the measured voltage of the battery 110 measured by a sensor and the estimated voltage of the battery 110 estimated by the battery model 410 may be determined.

In addition, the compensator 420 may determine a state variation (or an SOC error amount) of the battery 110 based on the determined voltage difference.

In an example, the compensator 420 may determine the state variation (or the SOC error amount) of the battery 110 based on the determined voltage difference, previous state information estimated in advance by the battery model 410, and an OCV table. The compensator 420 may obtain an OCV corresponding to the previous state information based on the OCV table, and determine the state variation of the battery 110 by reflecting the voltage difference to the obtained OCV.

In an example, the compensator 420 may determine a first OCP of each of electrodes of the battery 110 using a surface concentration (e.g., a stoichiometric concentration) of each electrode of the battery 110 estimated by the battery model 410. The compensator 420 may then determine a first OCV of the battery 110 using each determined first OCP. The compensator 420 may compensate the surface concentration of each electrode of the battery 110 based on an initial state variation. The compensator 420 may determine a second OCP of each of electrodes of the battery 110 using each compensated surface concentration. The compensator 420 may then determine a second OCV of the battery 110 using each determined second OCP. The compensator 420 may determine the state variation of the battery 110 using the determined first OCV, the determined second OCV, the initial state variation, and the determined voltage difference. The compensator 420 may determine a difference value between the determined second OCV and the determined first OCV, and determine the state variation of the battery 110 by applying a ratio between the determined difference value and the determined voltage difference to the initial state variation.

The compensator 420 may update the internal state of the battery model 410 based on the determined state variation. For example, the internal state of the battery model 410 may include one of a voltage, an overpotential, an SOC, a cathode lithium ion concentration distribution, an anode lithium ion concentration distribution, and an electrolyte lithium ion concentration distribution of the battery 110, or a combination of two or more thereof, and may be in the form of a profile. The compensator 420 may update the internal state of the battery model 410 by compensating an ion concentration distribution in an active material particle or an ion concentration distribution in an electrode based on the state variation of the battery 110.

The battery state estimation apparatus 120 may estimate state information of the battery 110 based on the updated internal state of the battery model 410.

As described above, the battery state estimation apparatus 120 may estimate the state information of the battery 110 at a high accuracy without increasing the complexity and computation amount of the model, through a feedback structure that updates the internal state of the battery model 410 by determining the state variation of the battery 110 such that the voltage difference between the measured voltage of the battery 110 and the estimated voltage estimated by the battery model 410 is minimized.

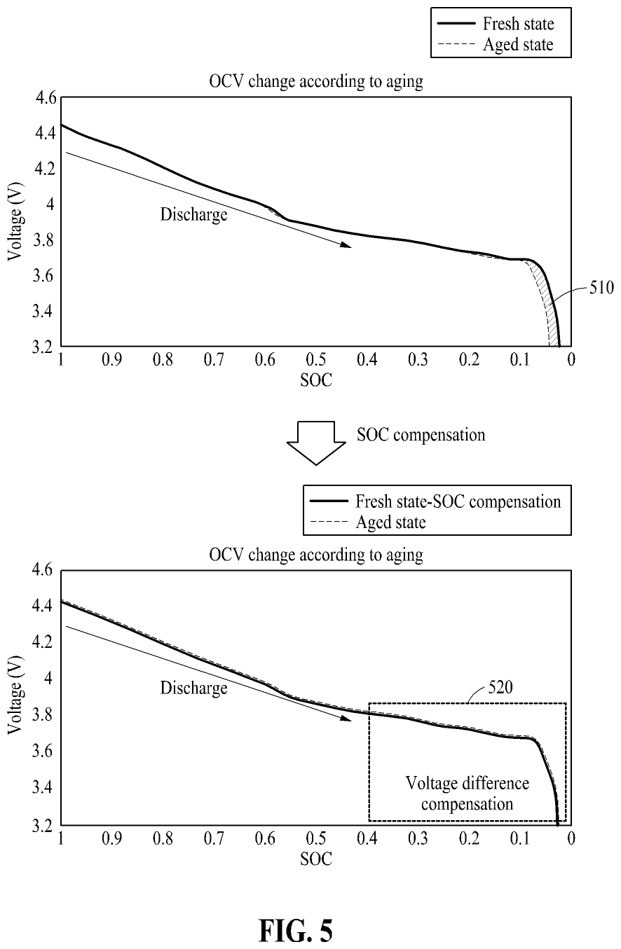

The operation of the compensator 420 described above may be used to estimate and update the electrode balance shift, which will be described in greater detail below with reference to FIG. 5.

FIG. 5 illustrates an example process of operating a compensator according to one or more embodiments.

Referring to FIG. 5, in a non-limiting example, cell voltages in a fresh state, an aged state, and a state in which SOC compensation is performed in the fresh state are illustrated.

In an example, when the battery model 410 estimates state information (e.g., an SOC) of the battery 110, the estimated voltage (e.g., the cell voltage in the fresh state shown in FIG. 5) of the battery model 410 may be compensated to match a measured voltage (e.g., the cell voltage in the aged state shown in FIG. 5) of the battery 110. At this time, a voltage difference between the measured voltage and the estimated voltage may be reduced through the SOC compensation by the battery model 410. A cumulative SOC compensation amount is a value for compensating for a voltage difference by the electrode balance shift, and the battery state estimation apparatus 120 may use a degree in which the state information of the battery 110 is compensated by the compensator 420, to estimate and update an electrode balance shift which is an aging parameter.

In an example, the cumulative SOC compensation amount may be determined based on a degree 510 in which the cell voltage in the fresh state is to be compensated to the cell voltage in the aged state by the compensator 420. Using a characteristic that the cumulative SOC compensation amount by the compensator 420 is determined according to a degree of aging of the battery 110, the battery state estimation apparatus 120 may update an aging parameter (e.g., an electrode balance shift) of the battery model 410 by converting a cumulative SOC compensation amount by the compensator 420 in a predetermined interval into an electrode balance shift value. The predetermined interval may be a region 520 in which the voltage difference is compensated by the compensator 420, and for example, a starting point of the predetermined interval may be between 30% and 40%, inclusive, for an SOC of the battery 110 or between 0.3 and 0.4, inclusive, for an anode stoichiometric concentration of the battery 110.

The electrode balance shift may therefore be determined based on the cumulative SOC compensation amount up to a fully discharged point in time, and the battery 110 may be charged first before the battery 110 reaches the fully discharged point in time according to a use pattern of a user of the battery or an environment in which the battery is in. Here, the fully discharged point in time may correspond to an SOC value when a discharge cutoff voltage is reached during standard discharge at room temperature. The electrode balance shift may be accurately estimated, in an example, where it is possible to estimate a cumulative SOC compensation amount at the fully discharged point in time from a cumulative SOC compensation amount until a discharged point in time before the fully discharged point in time is reached (e.g., a partially discharged point in time). An operation of estimating the cumulative SOC compensation amount at the fully discharged point in time from the cumulative SOC compensation amount at the partially discharged point in time and estimating the electrode balance shift using the same will be described in greater detail below with reference to the following drawings.

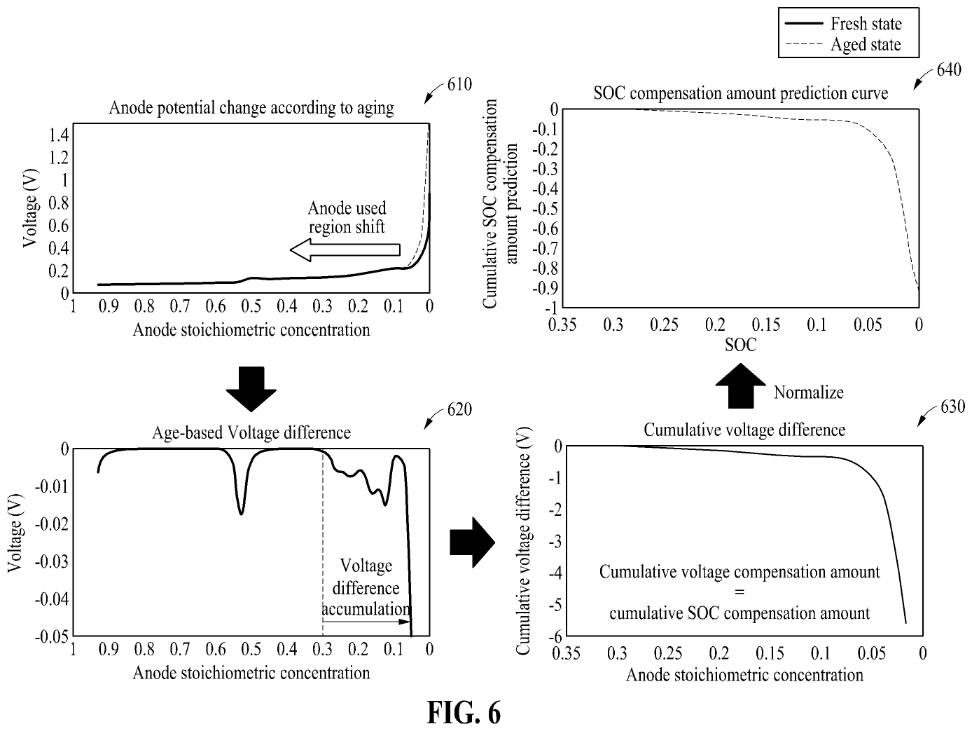

FIG. 6 illustrates example processes of determining a state of charge (SOC) compensation amount prediction curve according to one or more embodiments. Referring to FIG. 6, in a non-limiting example, an SOC compensation amount prediction curve 640 may be determined to estimate a second cumulative SOC compensation amount at a fully discharged point in time from a first cumulative SOC compensation amount at a partially discharged point in time. In FIG. 6, the x-axis of the graphs is denoted as an anode stoichiometric concentration for ease of description, but the x-axis may also be expressed as an SOC in an example. The anode stoichiometric concentration may correspond to a lithium concentration of the battery and may have an absolute value, while an SOC is a relative value and may have a designated position that may vary from 0% to 100% depending on an application or an example.

When a battery is aged due to an electrode balance shift, the SOC compensation amount prediction curve 640 may be determined based on a characteristic that a voltage difference between a cell voltage in an aged state (e.g., an estimated voltage of a battery model in an assumed aged state or a measured voltage of the aged battery) and a cell voltage in a fresh state (e.g., an estimated voltage of an electrochemical model not reflecting aging) has a predetermined pattern. Being aged due to an electrode balance shift may be a shift of a used region of an anode, and an anode potential difference caused by the shift may be the same as a voltage compensated when estimating the electrode balance shift. In other words, the value of the electrode balance shift may correspond to the characteristic of the anode potential difference caused by the shift.

An interval in which the electrode balance shift may be estimated is a region in which the anode potential difference significantly increases, and may be, in an example, an interval in which the anode stoichiometric concentration X is 0.3 or less. In other words, the electrode balance shift may be estimated in an interval in which X<0.3, and an interval in which X<0.3 during 0.5 C discharge may correspond to an interval in which the SOC is 40% or less. However, a starting point of the interval in which the electrode balance shift may be estimated is not limited to X=0.3, and the starting point may be X=0.3 to 0.4 in some examples.

An age-based voltage difference graph 620 shown in FIG. 6 illustrates, in an example, a voltage difference between an anode potential in a fresh state and an anode potential in an aged state which may be derived by an anode potential change graph 610 according to aging. The shapes of the graphs may be predetermined according to a battery in use. In other words, the age-based voltage difference graph 620 may have the same shape for batteries having the same characteristics (e.g., battery material, etc.). A cumulative SOC compensation amount used to estimate an electrode balance shift is obtained by accumulating SOC values to compensate for a voltage difference (or an anode potential difference), and may have a predetermined pattern when the age-based voltage difference graph 620 is fixed.

A cumulative voltage difference graph 630 may be determined by accumulating voltage differences from a predetermined point in time in the age-based voltage difference graph 620. The predetermined point in time is a point in time at which the voltage difference starts to gradually increase in the age-based voltage difference graph 620, and may be, for example, a point in time at which the anode stoichiometric concentration X is between 0.3 and 0.4, inclusive, as described above. Although the cumulative voltage difference graph 630 has a peak in an interval in which the anode stoichiometric concentration is 0.50 to 0.55, it is difficult to predict a cumulative SOC compensation amount for that particular interval. Thus, voltage differences during the interval may not be accumulated.

Because the cumulative SOC compensation amount for estimating the electrode balance shift is based on the same characteristics as the cumulative voltage difference graph 630, corresponding to the cumulative SOC compensation amount, the SOC compensation amount prediction curve 640 may be determined from the cumulative voltage difference graph 630. In an example, the SOC compensation amount prediction curve 640 may be determined by normalizing a y-axis data range of the cumulative voltage difference graph 630. The cumulative voltage difference graph 630 is normalized to reduce data usage for data processing, and in an example, the SOC compensation amount prediction curve 640 may be determined to be the same as the cumulative voltage difference graph 630.

Because the SOC compensation amount prediction curve 640 has a fixed pattern according to battery characteristics, the SOC compensation amount prediction curve 640 may be predetermined before estimating the electrode balance shift, and the predetermined SOC compensation amount prediction curve 640 may be simply applied when estimating the electrode balance shift.

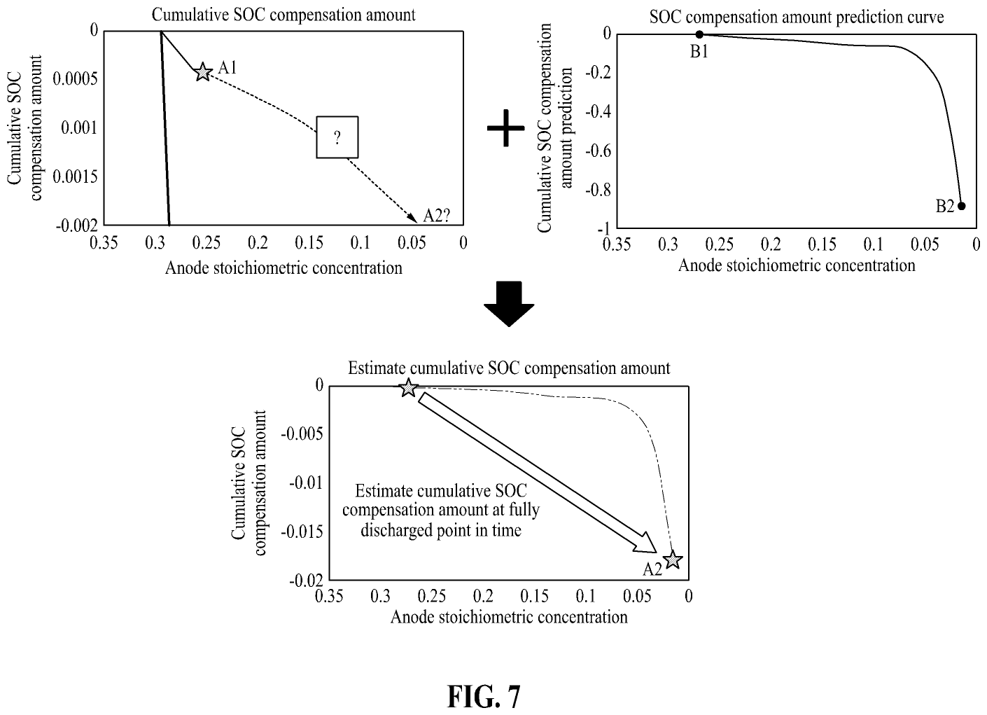

FIG. 7 illustrates example processes of estimating a cumulative SOC compensation amount according to one or more embodiments. Referring to FIG. 7, in a non-limiting example, an estimation of a second cumulative SOC compensation amount A2 at a fully discharged point in time from a first cumulative SOC compensation amount A1 at a partially discharged point in time based on a predetermined SOC compensation amount prediction curve is illustrated.

The first cumulative SOC compensation amount A1 may be measured at the partially discharged point in time. In an example, the partially discharged point in time is a not-fully discharged point in time at which an anode stoichiometric concentration X is 0.3 or less, and may be a point in time at which an SOC is between 15% and 40%, inclusive, but is not limited thereto.

A third cumulative SOC compensation amount B1 corresponding to a battery state (e.g., the anode stoichiometric concentration, the SOC, etc.) at the partially discharged point in time may be determined in the predetermined SOC compensation amount prediction curve illustrated in FIG. 6. In addition, a fourth cumulative SOC compensation amount B2 corresponding to a battery state at the fully discharged point in time may be determined in the SOC compensation amount prediction curve. The battery state at the fully discharged point in time may be an SOC or an anode stoichiometric concentration value when a discharge cutoff voltage is reached during standard discharge at room temperature.

In an example, second cumulative SOC compensation amount A2 at the fully discharged point in time may be determined based on Equation 1 below.

$$A 2 = A 1 \frac{B 2}{B 1} \qquad Equation 1$$

The second cumulative SOC compensation amount A2 at the fully discharged point in time may be converted into an electrode balance shift value based on Equation 2 below.

$$Electrode balance shift = A 2 \times ( {X}_{SOC 100 \%} - {X}_{SOC 0 \%} ) \qquad Equation 2$$

In Equation 2 above, X_{SOC100%} may be an anode stoichiometric concentration value corresponding to an SOC of 100%, and X_{SOC0%}, may be an anode stoichiometric concentration value corresponding to an SOC of 0%.

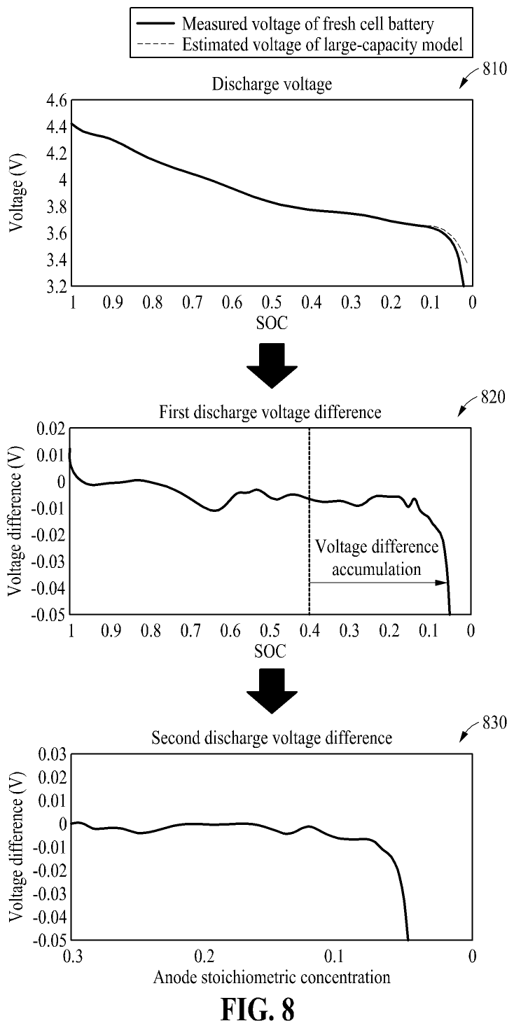

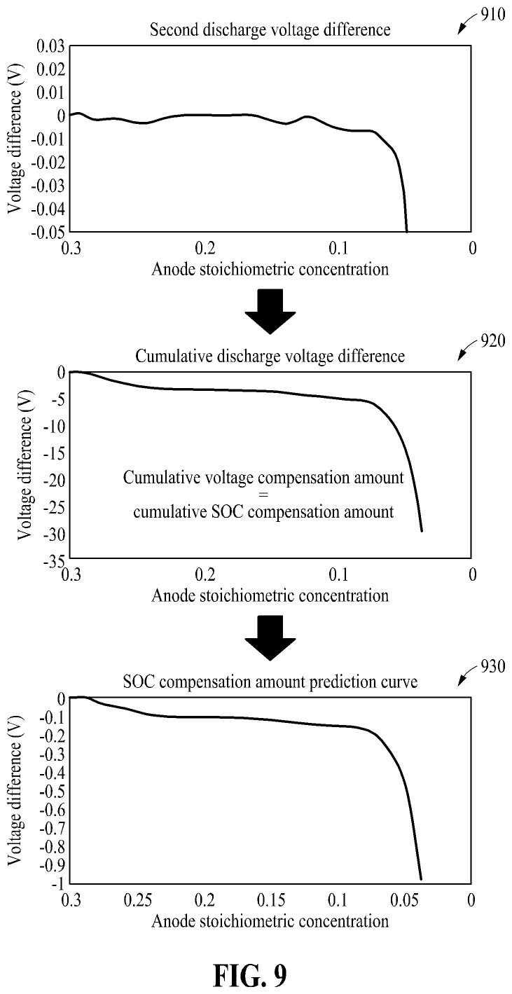

FIGS. 8 and 9 illustrate example processes of determining an SOC compensation amount prediction curve according to one or more embodiments.

The operation of determining the SOC compensation amount prediction curve 640 described above with reference to FIG. 6 may be based on an assumption that a measured voltage of an actual fresh cell battery and an estimated voltage of an electrochemical model in a fresh state are the same or substantially similar to each other. In other words, by applying the assumption that there is no or considerably small model error, the anode potential change graph 610 may be used to determine the SOC compensation amount prediction curve 640.

Because, without the above assumption, in an example, the measured voltage of the actual fresh cell battery and the estimated voltage of the battery model in the fresh state are not the same due to a model error, the model error may be reflected in a voltage difference graph used to determine the SOC compensation amount prediction curve, which is described in greater detail below.

Referring to FIG. 8, in a non-limiting example, a process of determining a second discharge voltage difference graph 830 reflecting a model error is illustrated.

In an example, a discharge voltage graph 810 may be about a measured voltage of a fresh cell battery and an estimated voltage of a large-capacity model, during low-current discharge (e.g., 0.2 C discharge). The large-capacity model may be a model with a model capacity intentionally increased by adjusting capacity parameters of an electrochemical model. For example, the capacity of the large-capacity model may be about 102% of the capacity of the electrochemical model, but is not limited thereto.

The electrochemical model may need to be updated when aging by an electrode balance shift causes a voltage difference between a fresh cell battery and an aged cell battery. Here, the fresh cell battery may correspond to a state of being less aged and having a larger battery capacity than the aged cell battery, and the aged cell battery may correspond to a state of being more aged (i.e., older and/or having experienced more usage) and having a smaller battery capacity than the fresh cell battery. To determine a voltage difference curve, data from a high-capacity model with a larger battery capacity and a cell battery having a relatively smaller battery capacity may be required. For example, when the anode moves in a negative direction when aging by the electrode balance shift occurs, a large-capacity model may be implemented by shifting the anode by an amount corresponding to an SOC of 2% in a positive direction. Alternatively, a large-capacity model may be implemented by enlarging an electrode area parameter, of the model parameters, to a level of 102%.

In an example, a first discharge voltage difference graph 820 may represent a difference between the measured voltage of the fresh cell battery and the estimated voltage of the large-capacity model shown in the discharge voltage graph 810. The first discharge voltage difference graph 820 from a predetermined point in time may be used to determine a cumulative discharge voltage difference 920 as shown below in FIG. 9. As described above, the predetermined point in time may be a point in time at which an SOC is between 30% and 40%, inclusive. However, in FIG. 8, for ease of description, the predetermined point in time may be determined to be a point in time at which an SOC is 40%.

The second discharge voltage difference graph 830 shows only a part of the graph after the predetermined point in time in the first discharge voltage difference graph 820 with respect to an anode stoichiometric concentration, and an offset value may be applied to a voltage difference value at the predetermined point in time to make the voltage difference value to be “0”.

Referring to FIG. 9, in a non-limiting example, a process of determining an SOC compensation amount prediction curve 930 from a second discharge voltage difference graph 910 is illustrated. The cumulative discharge voltage difference graph 920 may be determined by accumulating voltage differences from a predetermined point in time (e.g., anode stoichiometric concentration X=0.3) in the second discharge voltage difference graph 910. The SOC compensation amount prediction curve 930 may be determined based on the cumulative discharge voltage difference graph 920. In an example, the SOC compensation amount prediction curve 930 may be determined by normalizing a y-axis data range of the cumulative discharge voltage difference graph 920. The cumulative discharge voltage difference graph 920 is normalized to reduce data usage for data processing, and in an example, the SOC compensation amount prediction curve 930 may be determined to be the same as the cumulative discharge voltage difference graph 920.

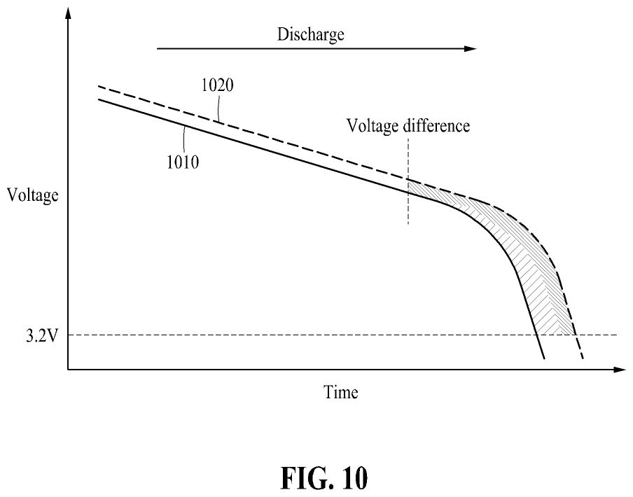

FIG. 10 illustrates an example of a voltage difference according to one or more embodiments.

Referring to FIG. 10, in a non-limiting example, a measured voltage 1010 of the battery 110 and an estimated voltage 1020 determined by a battery model (e.g., an electrochemical model) are illustrated.

In FIG. 10, in an example, SOC compensation amounts may be accumulated from when the anode stoichiometric concentration X of the battery 110 is 0.3. As described above, the battery state estimation apparatus 120 may estimate the second cumulative SOC compensation amount at the fully discharged point in time of the battery 110.

In an example, a voltage difference may occur at the start of an interval in which the SOC compensation amounts are accumulated. In an example, the estimated voltage 1020 may be greater than the measured voltage 1010 at the start of the interval in which the SOC compensation amounts are accumulated. In an example, unlike the example illustrated in FIG. 10, the measured voltage 1010 may be greater than the estimated voltage 1020 at the start of the interval in which the SOC compensation amounts are accumulated. When there is a voltage difference at the start of the interval in which the SOC compensation amounts are accumulated, the second cumulative SOC compensation amount may reflect an SOC error amount corresponding to the voltage difference.

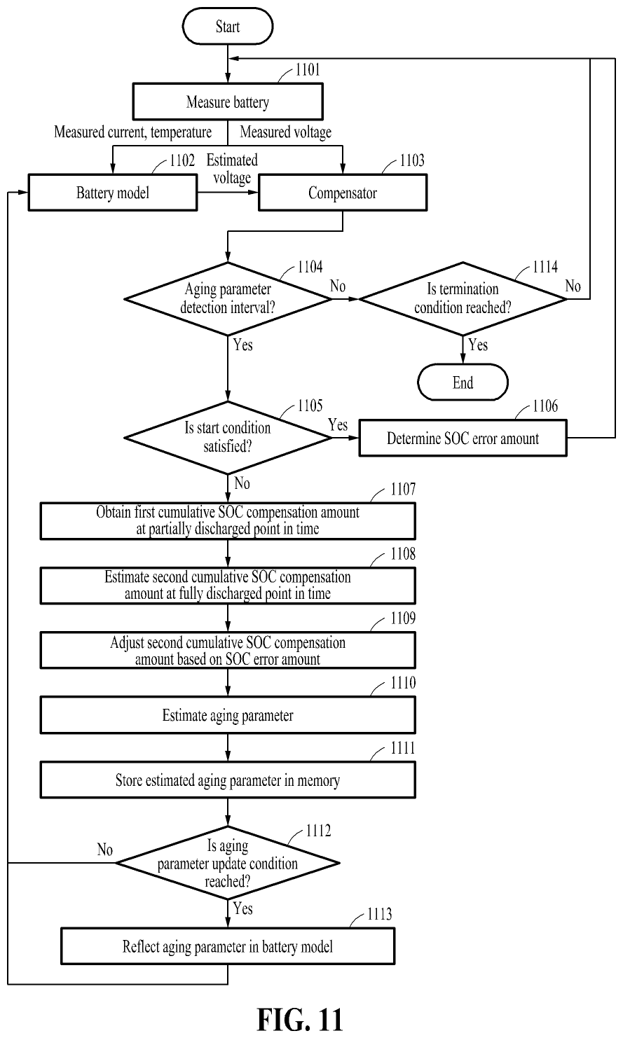

In an example, a battery state estimation apparatus (e.g., the battery state estimation apparatus 120) may determine whether a start condition for determining the SOC error amount is satisfied. Here, the start condition may include, for example, a condition in which the anode stoichiometric concentration X of the battery 110 is a predetermined concentration value (e.g., 0.3) or a condition in which the SOC of the battery 110 is a predetermined SOC value (e.g., 0.4). When the start condition is satisfied, the battery state estimation apparatus may determine the voltage difference between the measured voltage 1010 and the estimated voltage 1020, and determine the SOC error amount at a starting point in time (e.g., a point in time at which the start condition is satisfied) based on the determined voltage difference. The battery state estimation apparatus may estimate the second cumulative SOC compensation amount at the fully discharged point in time of the battery, and adjust the second cumulative SOC compensation amount based on the determined SOC error amount. As will be described in greater below, the battery state estimation apparatus may estimate an aging parameter of a battery model based on the adjusted second cumulative SOC compensation amount. Accordingly, the battery state estimation apparatus may more accurately estimate the aging parameter of the battery model. The method of estimating the battery state will be described below with reference to FIG. 11.

FIG. 11 illustrates an example method of estimating a battery state according to one or more embodiments.

Referring to FIG. 11, in a non-limiting example, in operation 1101, a battery state estimation apparatus (e.g., the battery state estimation apparatus 120) may measure a battery (e.g., the battery 110). For example, the battery state estimation apparatus may measure one of a voltage, a current, and a temperature of the battery, or a combination of two or more thereof. The measured data may be in the form of a profile indicating a change in size over time.

In operation 1102, the battery state estimation apparatus may determine an estimated voltage of the battery and one of state information (e.g., an SOC, RSOC, SOH, etc.) or a combination of two thereof through a battery model (e.g., an electrochemical model). In an example, the battery model may consider one of the current and the temperature measured in operation 1101 or a combination of the two.

In operation 1103, the battery state estimation apparatus may compensate one or a combination of the two of internal states of the battery model based on a voltage difference dV between a measured voltage and the estimated voltage through the compensator 420.

In operation 1104, the battery state estimation apparatus may determine whether a state (e.g., an aged state or the like) of the battery corresponds to a detection interval of an aging parameter (e.g., an electrode balance shift) of the battery model. In an example, when an anode concentration (e.g., stoichiometric concentration) of the battery is less than or equal to a predetermined concentration value (e.g., 0.3) and/or when the SOC determined in operation 1102 is less than or equal to a predetermined SOC value (e.g., 0.4), the battery state estimation apparatus may determine that the state of the battery corresponds to the detection interval of the aging parameter.

When the battery state estimation apparatus determines that the state of the battery corresponds to the detection interval of the aging parameter, in operation 1105, the battery state estimation apparatus may determine whether a start condition (e.g., a condition for starting operation 1106) is satisfied. The start condition may include, for example, a condition in which the anode concentration (e.g., the stoichiometric concentration) of the battery is a predetermined concentration value (e.g., 0.3) and/or a condition in which the state information (e.g., the SOC) of the battery is a predetermined SOC value (e.g., 0.4). The battery state estimation apparatus may determine that the start condition is satisfied when the anode concentration (e.g., the stoichiometric concentration) of the battery is the predetermined concentration value (e.g., 0.3), and then perform operation 1106. The battery state estimation apparatus may determine that the start condition is not satisfied when the anode concentration (e.g., the surface concentration) of the battery is less than the predetermined concentration value (e.g., 0.3), and then perform operation 1107. The battery state estimation apparatus may determine that the start condition is satisfied when the SOC value of the battery is the predetermined SOC value (e.g., 0.4), and perform operation 1106. The battery state estimation apparatus may determine that the start condition is not satisfied when the SOC value of the battery is less than the predetermined SOC value (e.g., 0.4), and perform operation 1107.

When the battery state estimation apparatus determines that the start condition is satisfied, in operation 1106, the battery state estimation apparatus may determine an SOC error amount at a point in time at which the start condition is satisfied (e.g., a point in time at which an anode surface concentration of the battery is a predetermined concentration value or a point in time at which the SOC value of the battery is the predetermined SOC value). In an example, the battery state estimation apparatus may determine the voltage difference dV at the point in time at which the start condition is satisfied, and determine the SOC error amount at the point in time at which the start condition is satisfied based on the voltage difference dV at the point in time at which the start condition is satisfied. The battery state estimation apparatus may determine the SOC error amount at the point in time at which the start condition is satisfied as an offset value used to adjust the second cumulative SOC compensation amount. A method of determining the SOC error amount at the point in time at which the start condition is satisfied will be described in greater detail below.

When it is determined that the start condition is not satisfied, in operation 1107, the battery state estimation apparatus may obtain a first cumulative SOC compensation amount at a partially discharged point in time. In other words, when it is determined that the start condition is not satisfied although the state of the battery is in the detection interval of the aging parameter, in operation 1107, the battery state estimation apparatus may obtain the first cumulative SOC compensation amount at the partially discharged point in time.

In operation 1108, the battery state estimation apparatus may estimate a second cumulative SOC compensation amount at a fully discharged point in time based on an SOC compensation amount prediction curve and the first cumulative SOC compensation amount.

In operation 1109, the battery state estimation apparatus may adjust the second cumulative SOC compensation amount based on the SOC error amount (e.g., the SOC error amount or the offset value determined in operation 1106). The battery state estimation apparatus may adjust the second cumulative SOC compensation amount by reflecting (or applying) the offset value to the second cumulative SOC compensation amount. In an example, when the measured voltage (or a sensed voltage) is less than the estimated voltage, in operation 1106, the battery state estimation apparatus may determine a first offset value. The battery state estimation apparatus may adjust the second cumulative SOC compensation amount by adding the first offset value to the second cumulative SOC compensation amount. In an example, when the measured voltage (or the sensed voltage) is greater than the estimated voltage, in operation 1106, the battery state estimation apparatus may determine a second offset value. The battery state estimation apparatus may adjust the second cumulative SOC compensation amount by subtracting the second offset value from the second cumulative SOC compensation amount.

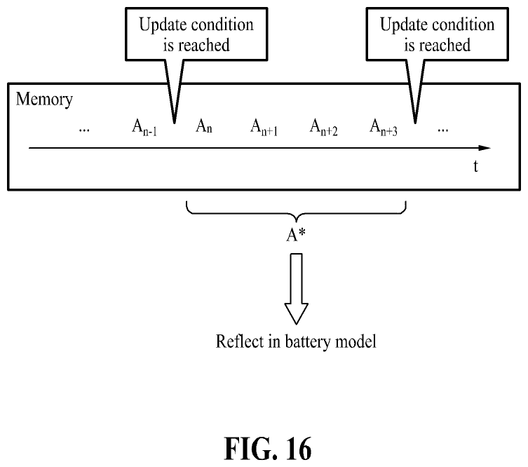

In operation 1110, the battery state estimation apparatus may estimate the aging parameter of the battery model based on the adjusted second cumulative SOC compensation amount. In an example, when a time point is defined as n, the battery state estimation apparatus may calculate an aging parameter value (i.e., Aₙ to be described in greater detail below with reference to FIG. 16) (e.g., an electrode balance shift value) at the time point n based on the adjusted second cumulative SOC compensation amount.

In operation 1111, the battery state estimation apparatus may store the estimated aging parameter (e.g., the calculated aging parameter value) in a memory. In an example, the memory may be an internal memory (e.g., memory 1920) of the battery state estimation apparatus or an external memory connected to the battery state estimation apparatus through a wired and/or wireless network.

In operation 1112, the battery state estimation apparatus may determine whether an update condition for the aging parameter is reached. This will be described in greater detail below with reference to FIG. 16. When the update condition is reached, the battery state estimation apparatus may perform operation 1113. When the update condition is not reached, the battery state estimation apparatus may perform operation 1102.

In operation 1113, the battery state estimation apparatus may reflect the aging parameter in the battery model. The battery state estimation apparatus may update an electrode balance shift value of the battery model using one or more aging parameter values stored in the memory. This will be described below in greater detail with reference to FIG. 16.

In an example, some or all of model parameters of the battery model may mutually affect each other, and thus a change in one model parameter may affect another model parameter. The battery state estimation apparatus may further update model parameters other than the electrode balance shift value of the battery model based on the electrode balance shift value.

Returning to operation 1104, the battery state estimation apparatus may determine that the state of the battery does not correspond to the detection interval of the aging parameter. In this case, in operation 1114, the battery state estimation apparatus may determine whether a termination condition is reached. In an example, the battery state estimation apparatus may determine whether the termination condition is reached based on whether a predetermined operating time has elapsed. When the predetermined operating time has not elapsed, the battery state estimation apparatus may perform operation 1101. When the predetermined operating time has elapsed, the battery state estimation apparatus may terminate the operation of estimating the battery state.

Through the operation of the battery state estimation apparatus as described above, even when the battery is not fully discharged depending on a use pattern or environment of the battery 110, an electrode balance shift value may be accurately estimated and reflected in the battery model.

Through the electrochemical model reflecting the actual aged state of the battery 110, it is possible to estimate state information of the battery at a high accuracy even in an aged state and to effectively suppress aging accelerated by fast charging or discharging through an accurate state diagnosis of the battery 110, which may thereby enhance the safety of the battery 110.

For a more detailed description of the operations described with reference to FIG. 11, reference may be made to what has been described above with reference to FIGS. 1 through 10.

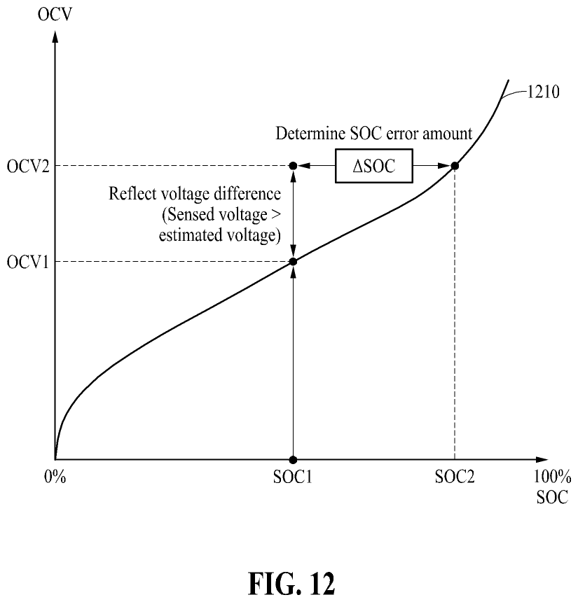

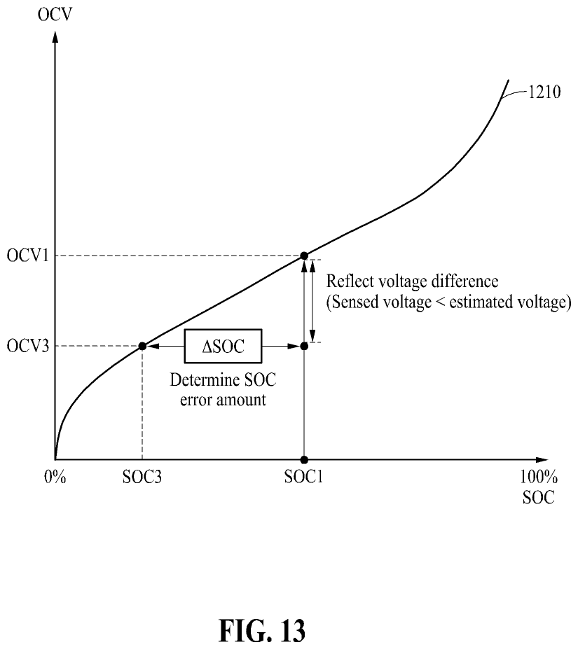

FIGS. 12 and 13 illustrate example processes of determining an SOC error amount by a battery state estimation apparatus according to one or more embodiments. In an example, the operation to be described with reference to FIGS. 12 and 13 may be included in operation 1106 of FIG. 11.

Referring to FIG. 12, in a non-limiting example, a sensed voltage (or a measured voltage) of the battery 110 may be greater than an estimated voltage estimated by a battery model (e.g., an electrochemical model) at a starting point in time (e.g., a point in time at which an anode concentration of a battery is a predetermined concentration value or a point in time at which an SOC of a battery is a predetermined SOC value). When the sensed voltage is greater than the estimated voltage, the voltage difference dV may be, in an example, a positive number.

The battery state estimation apparatus 120 may determine the SOC (hereinafter, referred to as SOC1) of the battery 110 by the battery model in operation 1102 of FIG. 11.

A graph 1210 of FIG. 12 may represent a graph between an SOC and an OCV of the battery 110 and may represent unique characteristics of the battery 110. An OCV table may correspond to the graph 1210.

The battery state estimation apparatus 120 may determine the OCV (hereinafter, referred to as “OCV1”) corresponding to the SOC1 determined by the battery model through the OCV table (or the graph 1210). The battery state estimation apparatus 120 may reflect the voltage difference dV at the starting point in time in the OCV1. In an example, the battery state estimation apparatus 120 may reflect the voltage difference dV in the OCV1 by adding the voltage difference dV to the OCV1. In the example shown in FIG. 12, the sensed voltage may be greater than the estimated voltage, and thus, the OCV (hereinafter, referred to as “OCV2”) reflecting the voltage difference dV (e.g., OCV2=OCV1+dV) may be greater than the OCV1.

The battery state estimation apparatus 120 may determine the SOC (hereinafter, referred to as “SOC2”) corresponding to the OCV2 using the OCV table (or the graph 1210). In the example shown in FIG. 12, the SOC2 may correspond to the SOC obtained by compensating the SOC1 by the battery state estimation apparatus 120. The battery state estimation apparatus 120 may determine a difference between the SOC2 and the SOC1 as an SOC error amount at the starting point in time, and determine the determined SOC error amount as an offset value (e.g., the second offset value described in operation 1109 of FIG. 11).

Referring to FIG. 13, in a non-limiting example, the sensed voltage (or the measured voltage) of the battery 110 at the starting point in time may be smaller than the estimated voltage estimated by the battery model. In this case, the voltage difference dV may be, for example, a negative number.

The battery state estimation apparatus 120 may determine the OCV1 corresponding to the SOC1 determined by the battery model through the OCV table (or the graph 1210).

The battery state estimation apparatus 120 may reflect the voltage difference dV at the starting point in time in the OCV1. In the example shown in FIG. 13, the sensed voltage may be less than the estimated voltage, and thus, the OCV (hereinafter, referred to as “OCV3”) reflecting the voltage difference dV (e.g., OCV3=OCV1+dV) may be less than the OCV1.

The battery state estimation apparatus 120 may determine the SOC (hereinafter, referred to as “SOC3”) corresponding to the OCV3 using the OCV table (or the graph 1210). In the example shown in FIG. 13, the SOC3 may correspond to the SOC obtained by compensating the SOC1 by the battery state estimation apparatus 120. The battery state estimation apparatus 120 may determine a difference between the SOC3 and the SOC1 as an SOC error amount at the starting point in time, and determine the determined SOC error amount as an offset value (e.g., the first offset value described in operation 1109 of FIG. 11).

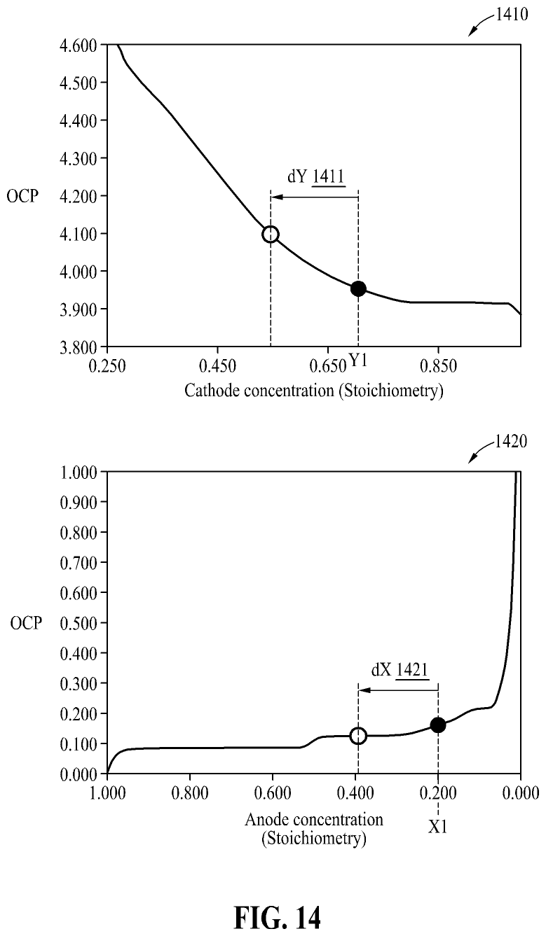

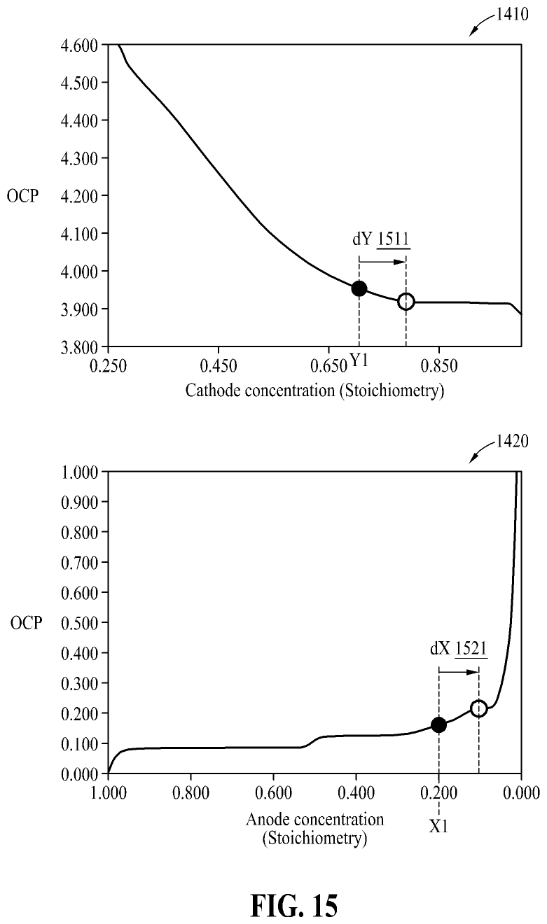

FIGS. 14 and 15 illustrate example processes of determining an SOC error amount by a battery state estimation apparatus according to one or more embodiments. The operation to be described with reference to FIGS. 14 and 15 may be included in operation 1106 of FIG. 11.

FIGS. 14 and 15, in non-limiting examples, show a graph 1410 corresponding to a first OCP table and a graph 1420 corresponding to a second OCP table. The first OCP table may correspond to, for example, an OCP table representing a relationship between a cathode stoichiometric concentration of the battery 110 and the OCP. The graph 1410 may represent a curve (or a graph) of the OCP according to the cathode stoichiometric concentration of the battery 110. The second OCP table may correspond to, for example, an OCP table representing a relationship between an anode stoichiometric concentration of the battery 110 and the OCP. The graph 1420 may represent a curve (or a graph) of the OCP according to the anode stoichiometric concentration of the battery 110.

In an example, the stoichiometric concentration may have an absolute value, while an SOC is a relative value and may have a designated position that may vary from 0% to 100% depending on an application.

In the example shown in FIG. 14, the battery state estimation apparatus 120 may determine a surface concentration of each electrode of the battery 110, the estimated voltage of the battery 110, and the SOC (hereinafter, referred to as “SOC1” in FIG. 14) of the battery 110 through the battery model. In operation 1102 of FIG. 11, the battery state estimation apparatus 120 may determine the surface concentration of each electrode of the battery 110, the estimated voltage of the battery 110, and the SOC1. In the example shown in FIG. 14, the battery state estimation apparatus 120 may determine a cathode surface concentration of the battery 110 as Y1, and determine an anode surface concentration of the battery 110 as X1.

The battery state estimation apparatus 120 may determine the voltage difference dV between the sensed voltage of the battery 110 and the estimated voltage of the battery 110. In an example, the estimated voltage may be less than the sensed voltage by 300 mV. The battery state estimation apparatus 120 may calculate the voltage difference dV as 300 mV according to “the sensed voltage—the estimated voltage”. A positive value (e.g., 300 mV) of the voltage difference dV may imply that the battery model determines the SOC1 to be less than an actual SOC of the battery 110 (e.g., an SOC of the battery 110 in a state in which various errors such as a sensor error and an error of the battery model are excluded) by the internal state (e.g., at least one parameter) of the battery model.

The battery state estimation apparatus 120 may obtain an OCP value (e.g., 3.95 V) corresponding to the cathode surface concentration Y1 from the first OCP table (or the graph 1410). The battery state estimation apparatus 120 may obtain an OCP value (e.g., 0.17 V) corresponding to the anode surface concentration X1 from the second OCP table (or the graph 1420).

The battery state estimation apparatus 120 may calculate a difference value (e.g., 3.78 V) between the OCP value (e.g., 3.95 V) corresponding to the cathode surface concentration Y1 and the OCP value (e.g., 0.17 V) corresponding to the anode surface concentration X1. The battery state estimation apparatus 120 may determine the calculated difference value (e.g., 3.78 V) as OCV1 of the battery 110. The OCV1 may, in an example, correspond to the OCV of the battery 110 in the SOC1.

The battery state estimation apparatus 120 may determine concentration movement amounts (or concentration variations) (e.g., dY 1411 and dX 1421 of FIG. 14) of the electrodes. The cathode concentration movement amount (or concentration variation) dY 1411 may indicate, for example, a degree that the cathode surface concentration Y1 is to be moved (or to be changed) in the graph 1410. The anode concentration movement amount (or concentration variation) dX 1421 may indicate, for example, a degree that the anode surface concentration X1 is to be moved (or to be changed) in the graph 1420. The surface concentration of each electrode may be compensated by the concentration movement amount (or concentration variation) of each electrode, and the concentration movement amount may thus be expressed as a compensation value (or concentration compensation amount). The compensation value (or concentration compensation amount) of each electrode may indicate a degree the surface concentration of each electrode is to be compensated.

The battery state estimation apparatus 120 may determine the concentration movement amount (or compensation value) dY 1411 for compensating the cathode surface concentration Y1 based on an initial SOC error amount d_SOC_0. The battery state estimation apparatus 120 may determine the concentration movement amount (or compensation value) dX 1421 for compensating the anode surface concentration X1 based on the initial SOC error amount d_SOC_0. The initial SOC error amount d_SOC_0 may have a fixed value, for example, but examples are not limited thereto. In an example, the battery state estimation apparatus 120 may determine the initial SOC error amount d_SOC_0 through the voltage difference dV and an OCV-SOC table (or the OCV-SOC graph 1210).

In an example, the battery state estimation apparatus 120 may determine dY 1411 (e.g., dY=d_SOC_0×d_SOC_CA) using the initial SOC error amount d_SOC_0 and a predetermined value d_SOC_CA for the cathode of the battery 110. The battery state estimation apparatus 120 may determine dX 1421 (e.g., dX=d_SOC_0×d_SOC_AN) using the initial SOC error amount d_SOC_0 and a predetermined value d_SOC_AN for the anode of the battery 110. In a case of the example shown in FIG. 14, the voltage difference dV may be a positive number, d_SOC_CA may be a negative number, and d_SOC_AN may be a positive number, as will be described in greater detail below. Accordingly, a relationship of “dY 1411<0” may be satisfied, and a relationship of “dX 1421>0” may be satisfied. The dY 1411 may be a direction in which the cathode concentration (e.g., the cathode surface concentration or stoichiometric concentration) decreases, and the dX 1421 may be a direction in which the anode concentration (e.g., the anode surface concentration or stoichiometric concentration) increases.

The predetermined value d_SOC_CA for the cathode may, for example, represent a difference between a cathode concentration corresponding to SOC=100% and a cathode concentration corresponding to SOC=0%. For example, the cathode concentration corresponding to SOC=100% may be 0.3, and the cathode concentration corresponding to SOC=0% may be 0.9. In this case, the predetermined value d_SOC_CA for the cathode may be −0.6.

The predetermined value d_SOC_AN for the anode may, for example, represent a difference between an anode concentration corresponding to SOC=100% and an anode concentration corresponding to SOC=0%. In an example, the anode concentration corresponding to SOC=100% may be 0.9, and the anode concentration corresponding to SOC=0% may be 0.01. In this case, the predetermined value d_SOC_AN for the anode may be 0.89.

The battery state estimation apparatus 120 may compensate the cathode surface concentration Y1 through the dY 1411. The compensated cathode surface concentration Y1+dY may correspond to a position where the cathode surface concentration Y1 is moved by dY 1411 on the graph 1410. The compensated cathode surface concentration Y1+dY may be less than the cathode surface concentration Y1. The battery state estimation apparatus 120 may obtain an OCP value (e.g., 4.1 V) corresponding to the compensated (or moved) cathode surface concentration Y1+dY in the first OCP table (or the graph 1410).

The battery state estimation apparatus 120 may compensate the anode surface concentration X1 through the dX 1421. The compensated anode surface concentration X1+dX may correspond to a position where the anode surface concentration X1 is moved by dX 1421 on the graph 1420. The compensated anode surface concentration X1+dX may be more than the anode surface concentration X1. The battery state estimation apparatus 120 may obtain an OCP value (e.g., 0.13 V) corresponding to the compensated (or moved) anode surface concentration X1+dX in the second OCP table (or the graph 1420).

In an example, the battery state estimation apparatus 120 may calculate a difference value (e.g., 3.97 V) between the OCP value (e.g., 4.1 V) corresponding to the compensated cathode surface concentration and the OCP value (e.g., 0.13 V) corresponding to the compensated anode surface concentration. The battery state estimation apparatus 120 may determine the calculated difference value (e.g., 3.97 V) as the OCV2 of the battery 110.

The battery state estimation apparatus 120 may determine an SOC error amount d_SOC of the battery 110 using the initial SOC error amount d_SOC_0, the OCV1 of the battery 110, the OCV2 of the battery 110, and the voltage difference dV. In an example, the battery state estimation apparatus 120 may determine the SOC error amount d_SOC of the battery 110 by Equation 3 below.

$$d\_SOC \_ 0 : d\_SOC = OCV difference : dV \qquad Equation 3$$

In an example, an absolute value may be applied to the OCV difference and/or dV in Equation 3 above.

A ratio between d_SOC_0 and d_SOC may be equal to a ratio between the OCV difference (e.g., OCV2−OCV1=3.97 V−3.78 V=0.19 V) and the voltage difference dV. When d_SOC_0 is, for example, 3%, d_SOC may be “3%×0.3/0.19=4.73%”. In other words, the battery state estimation apparatus 120 may determine d_SOC to be 4.73% by applying d_SOC_0 to the ratio between the OCV difference and the voltage difference dV. The battery state estimation apparatus 120 may determine the determined d_SOC (e.g., 4.73%) as an offset value (e.g., the second offset value described in operation 1109 of FIG. 11).

Unlike the example shown in FIG. 14, in the example shown in FIG. 15, the estimated voltage may be greater than the sensed voltage. Hereinafter, an example in which the battery state estimation apparatus 120 determines the SOC error amount when the estimated voltage is greater than the sensed voltage will be described below with reference to FIG. 15.

Referring FIG. 15, in a non-limiting example, the battery state estimation apparatus 120 may determine a surface concentration of each electrode of the battery 110, the estimated voltage of the battery 110, and the SOC (hereinafter, referred to as “SOC2” in FIG. 15) of the battery 110 through the battery model. In the example shown in FIG. 15, the battery state estimation apparatus 120 may determine a cathode surface concentration of the battery 110 as Y1, and determine an anode surface concentration of the battery 110 as X1.

In an example, the battery state estimation apparatus 120 may determine the voltage difference dV between the sensed voltage of the battery 110 and the estimated voltage of the battery 110. For example, the estimated voltage may be greater than the sensed voltage by 200 mV. The battery state estimation apparatus 120 may calculate the voltage difference dV as −200 mV according to “the sensed voltage—the estimated voltage”. A negative value (e.g., −200 mV) of the voltage difference dV may imply that the battery model determines the SOC2 to be greater than the actual SOC of the battery 110 by the internal state of the battery model.

The battery state estimation apparatus 120 may obtain an OCP value (e.g., 3.95 V) corresponding to the cathode surface concentration Y1 from the first OCP table (or the graph 1410). The battery state estimation apparatus 120 may obtain an OCP value (e.g., 0.17 V) corresponding to the anode surface concentration X1 from the second OCP table (or the graph 1420).

The battery state estimation apparatus 120 may calculate a difference value (e.g., 3.78 V) between the OCP value (e.g., 3.95 V) corresponding to the cathode surface concentration Y1 and the OCP value (e.g., 0.17 V) corresponding to the anode surface concentration X1. The battery state estimation apparatus 120 may determine the calculated difference value (e.g., 3.78 V) as the OCV1 of the battery 110.

When the voltage difference dV is a negative number, the battery state estimation apparatus 120 may change (or convert) the sign of the initial state variation d_SOC_0. For example, d_SOC_0 may be 3%. When the voltage difference dV is a positive number, the battery state estimation apparatus 120 may use d_SOC_0 without the sign change (or a sign conversion) as described above. When the voltage difference dV is a negative number, the battery state estimation apparatus 120 may change (or convert) d_SOC_0 to −3% through the sign change (or the sign conversion).

The battery state estimation apparatus 120 may determine a compensation value (or concentration movement amount) dY 1511 for compensating the cathode surface concentration Y1 based on a changed initial SOC error amount −d_SOC_0. The battery state estimation apparatus 120 may determine a compensation value (or concentration movement amount) dX 1521 for compensating the anode surface concentration X1 based on the changed initial SOC error amount −d_SOC_0.

In an example, the battery state estimation apparatus 120 may determine dY 1511 (e.g., dY=−d_SOC_0×d_SOC_CA) using the changed initial SOC error amount-d_SOC_0 and the predetermined value d_SOC_CA for the cathode of the battery 110. The battery state estimation apparatus 120 may determine dX 1521 (e.g., dX=d_SOC_0×d_SOC_AN) using the initial SOC error amount −d_SOC_0 and the predetermined value d_SOC_AN for the anode of the battery 110. Because the voltage difference dV is a negative number, the dY 1511 may be a direction in which the cathode concentration (e.g., the cathode surface concentration or stoichiometric concentration) increases, and the dX 1521 may be a direction in which the anode concentration (e.g., the anode surface concentration or stoichiometric concentration) decreases.

The battery state estimation apparatus 120 may compensate the cathode surface concentration Y1 through the dY 1511. The compensated cathode surface concentration Y1+dY may be greater than the cathode surface concentration Y1. The battery state estimation apparatus 120 may obtain an OCP value (e.g., 3.91 V) corresponding to the compensated cathode surface concentration Y1+dY in the first OCP table (or the graph 1410). The battery state estimation apparatus 120 may compensate the anode surface concentration X1 through the dX 1521. The compensated anode surface concentration X1+dX may be less than the anode surface concentration X1. The battery state estimation apparatus 120 may obtain an OCP value (e.g., 0.21 V) corresponding to the compensated anode surface concentration X1+dX in the second OCP table (or the graph 1420).

The battery state estimation apparatus 120 may calculate a difference value (e.g., 3.7 V) between the OCP value (e.g., 3.91 V) corresponding to the compensated cathode surface concentration and the OCP value (e.g., 0.21 V) corresponding to the compensated anode surface concentration. The battery state estimation apparatus 120 may determine the calculated difference value (e.g., 3.7 V) as the OCV3 of the battery 110.

The battery state estimation apparatus 120 may determine the SOC error amount d_SOC of the battery 110 using the changed initial SOC error amount −d_SOC_0, the OCV1 of the battery 110, the OCV3 of the battery 110, and the voltage difference dV. In an example, the battery state estimation apparatus 120 may determine the SOC error amount d_SOC of the battery 110 by Equation 3 above. According to Equation 3 above, a ratio between −d_SOC_0 and d_SOC may be equal to a ratio between the OCV difference (e.g., OCV3−OCV1=3.7 V−3.78 V=−0.08 V) and the voltage difference dV. When −d_SOC_0 is, for example, −3%, d_SOC may be “−3% x (−0.2)/(−0.08)=−7.5%”. In other words, in the example shown in FIG. 15, the battery state estimation apparatus 120 may determine d_SOC to be −7.5%. The battery state estimation apparatus 120 may determine the determined d_SOC (e.g., −7.5%) as an offset value (e.g., the first offset value described in operation 1109 of FIG. 11).

FIG. 16 illustrates an example method of updating an aging parameter according to one or more embodiments.

Referring to FIG. 16, in a non-limiting example, a calculated aging parameter value may be stored in a memory each time an aging parameter value is calculated and an aging parameter of an electrochemical model may be updated using one or more aging parameter values when an update condition is reached, rather than updating the aging parameter of the battery model immediately based on the calculated aging parameter value. In FIGS. 16, Aₙ₋₁, Aₙ, . . . , and Aₙ₊₃ may be aging parameter values that are sequentially calculated. Each of Aₙ₋₁, Aₙ, . . . , and Aₙ₊₃ of FIG. 16 is an electrode balance shift value calculated each time operation 1110 described above is performed, and may not yet be reflected in the electrochemical model.

In the example shown in FIG. 16, the update condition may be reached after the aging parameter value Aₙ₊₃ is calculated. In this case, a final parameter value A* to be used for updating the aging parameter may be determined based on one or more aging parameter values stored in the memory. In an example, the final parameter value A* may be determined to be a statistical value (e.g., an average value, a moving average value, a median value, a maximum value, etc.) of the aging parameter values Aₙ, . . . , and Aₙ₊₃ between a current point in time at which the update condition is reached and a last point in time (e.g., a point in time at which the update condition was last reached). The battery state estimation apparatus 120 may apply the final parameter value A* to the aging parameter (e.g., the electrode balance shift) of the battery model. Alternatively, the final parameter value A* may be determined to be a statistical value of n aging parameter values that have been most recently calculated based on the current point in time at which the update condition is reached (n being a natural number greater than 0). Depending on a circumstance (e.g., when n is “5”), the aging parameter value (e.g., Aₙ₋₁) used in the determination of a previous aging parameter may also be used for this update.

In an example, the update condition may be determined based on one of a number of cycles of the battery, a cumulative use capacity of the battery, a cumulative use time of the battery, and a number of aging parameter values stored in the memory, or a combination of two or more thereof. In an example, to update an aging parameter of the electrochemical model using multiple aging parameter values accumulated as the battery is charged and discharged a number of times, one of the number of cycles of the battery, the cumulative use capacity of the battery, the cumulative use time of the battery, and the number of aging parameters stored in the memory, or a combination of two or more thereof may be used as the update condition. However, the update condition is not limited thereto.

In an example, the battery state estimation apparatus 120 may store an adjusted second cumulative SOC compensation amount in a memory (e.g., the memory 1730) each time the second cumulative SOC compensation amount is adjusted. When the update condition is reached, the battery state estimation apparatus 120 may calculate an average value of one or more adjusted second cumulative SOC compensation amounts stored in the memory, and apply or reflect the calculated average value to the aging parameter (e.g., the electrode balance shift) of the battery model. In an example, the battery state estimation apparatus 120 may store a second cumulative SOC compensation amount (hereinafter, Sa) adjusted at a point in time a in the memory, and store a second cumulative SOC compensation amount (hereinafter, Sₐ₊₁) adjusted at a point in time a+1 in the memory. The battery state estimation apparatus 120 may store a second cumulative SOC compensation amount (hereinafter, referred to as Sₐ₊ₙ) adjusted at a point in time a+n. When the update condition is reached, the battery state estimation apparatus 120 may calculate an average value of the adjusted second cumulative SOC compensation amounts Sₐ, . . . , and Sₐ₊ₙ stored in the memory. The battery state estimation apparatus 120 may convert the calculated average value into an electrode balance shift value of the battery model by Equation 2 above. The battery state estimation apparatus 120 may apply or reflect the converted electrode balance shift value to the battery model. As a result, the electrode balance shift of the battery model may be updated.

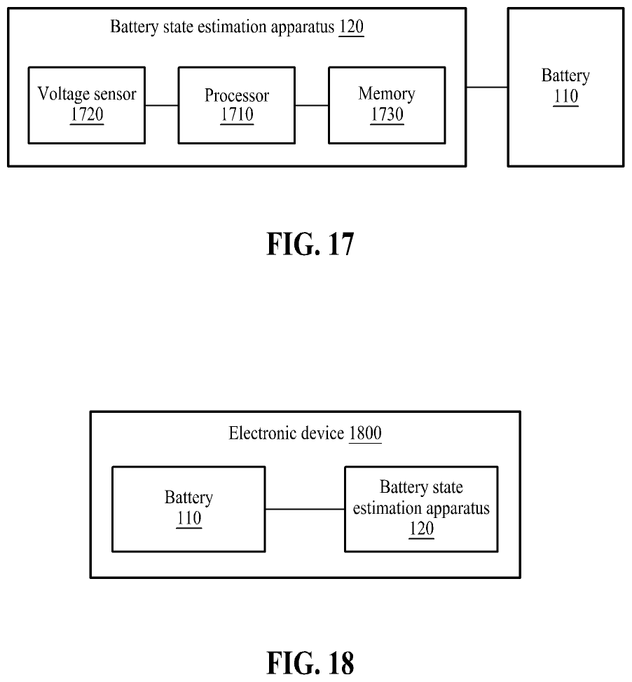

FIG. 17 illustrates an example configuration of an electronic apparatus according to one or more embodiments.

Referring to FIG. 17, in a non-limiting example, the battery state estimation apparatus 120 may include a processor 1710, a voltage sensor 1720, and a memory 1730.

The memory 1730 may include computer-readable instructions. The processor 1710 may be configured to execute computer-readable instructions, such as those stored in the memory 1730, and through execution of the computer-readable instructions, the processor 1710 is configured to perform one or more, or any combination, of the operations and/or methods described herein. The memory 1730 may be a volatile or nonvolatile memory. In an example, the memory 1730 may store a battery model (e.g., an electrochemical model).

In an example, the processor 1710 may determine a voltage difference dV between an estimated voltage of the battery 110 determined by the battery model and a sensed voltage (or a measured voltage) of the battery 110 obtained using the voltage sensor 1720. The processor 1710 may determine whether a start condition for determining an SOC error amount is satisfied. At this time, the processor 1710 may determine that the start condition is satisfied when an anode concentration (e.g., an anode surface concentration determined by the battery model) of the battery 110 has reached a predetermined concentration value or when an SOC (e.g., an SOC determined by the battery model) of the battery 110 has reached a predetermined SOC value. When the processor 1710 determines that the start condition is satisfied, the processor 1710 may determine the voltage difference at a point in time at which the start condition is satisfied.

The processor 1710 may determine an SOC error amount of the battery 110 based on the determined voltage difference. In an example, the processor 1710 may obtain an OCV corresponding to the SOC of the battery determined by the battery model from an OCV table. The processor 1710 may determine the SOC error amount of the battery 110 by reflecting the determined voltage difference in the obtained OCV. In an example, the processor 1710 may determine a first OCP of each of electrodes of the battery 110 using a surface concentration of each electrode of the battery 110. The processor 1710 may determine a first OCV of the battery 110 using each determined first OCP. The processor 1710 may compensate each surface concentration based on an initial SOC error amount. The processor 1710 may determine a second OCP of each of electrodes of the battery 110 using each compensated surface concentration. The processor 1710 may determine a second OCV of the battery 110 using each determined second OCP. The processor 1710 may determine the SOC error amount of the battery 110 using the determined first OCV, the determined second OCV, the initial SOC error amount, and the determined voltage difference. The processor 1710 may determine the determined SOC error amount as an offset value.

The processor 1710 may determine a first cumulative SOC compensation amount that is accumulated SOC compensation amounts used to compensate the SOC of the battery 110 at a partially discharged point in time of the battery 110.

The processor 1710 may estimate a second cumulative SOC compensation amount at a fully discharged point in time of the battery 110 based on the determined first cumulative SOC compensation amount and a predetermined SOC compensation amount prediction curve. In an example, the processor 1710 may obtain a third cumulative SOC compensation amount corresponding to a battery state (e.g., a partially discharged battery state) at the partially discharged point in time in the SOC compensation amount prediction curve. The processor 1710 may obtain a fourth cumulative SOC compensation amount corresponding to a battery state (e.g., a fully discharged battery state) at the fully discharged point in time in the SOC compensation amount prediction curve. The processor 1710 may estimate the second cumulative SOC compensation amount using the determined first cumulative SOC compensation amount, the obtained third cumulative SOC compensation amount, and the obtained fourth cumulative SOC compensation amount.

The processor 1710 may adjust the estimated second cumulative SOC compensation amount based on the SOC error amount (or the determined offset value) at the point in time at which the start condition is satisfied. For example, the processor 1710 may adjust the estimated second cumulative SOC compensation amount by subtracting the SOC error amount (or the offset value) (e.g., a second offset value) at the point in time at which the start condition is satisfied, from the estimated second cumulative SOC compensation amount. In an example, the processor 1710 may adjust the estimated second cumulative SOC compensation amount by adding the estimated second cumulative SOC compensation amount and the SOC error amount (or the offset value) (e.g., a first offset value). The first offset value and the second offset value may be, for example, positive numbers.

In an example, the processor 1710 may update an aging parameter of the battery model based on the adjusted second cumulative SOC compensation amount. In an example, the processor 1710 may store an aging parameter value calculated based on the adjusted second cumulative SOC compensation amount in the memory 1730. According to the implementation, the aging parameter value may be stored in a memory other than the memory 1730. When an update condition for the aging parameter is satisfied, the processor 1710 may update the aging parameter of the battery model using one or more aging parameter values stored in the memory 1730. For example, the processor 1710 may calculate an average value of electrode balance shift values stored in the memory 1730, and reflect or apply the calculated average value to an electrode balance shift of the battery model. Accordingly, the processor 1710 may update the electrode balance shift of the battery model. In an example, the processor 1710 may store the adjusted second cumulative SOC compensation amount in the memory 1730. According to the implementation, the adjusted second cumulative SOC compensation amount may be stored in a memory other than the memory 1730. When the update condition for the aging parameter is satisfied, the processor 1710 may calculate an average value of a plurality of adjusted second cumulative SOC compensation amounts stored in the memory 1730, and update the aging parameter of the battery model using the calculated average value. In an example, the processor 1710 may calculate an electrode balance shift value by multiplying a difference value between X_{SOC100%} and X_{SOC0%}, by the average value of the plurality of adjusted second cumulative SOC compensation amount by Equation 2 above, and reflect or apply the calculated electrode balance shift value to the electrode balance shift of the battery model. Accordingly, the processor 1710 may update the electrode balance shift of the battery model.

The processor 1710 may be configured to execute programs or applications to configure the processor 1710 to control the battery state estimation apparatus 120 to perform one or more or all operations and/or methods involving battery state estimation, and may include any one or a combination of two or more of, for example, a central processing unit (CPU), a graphic processing unit (GPU), a neural processing unit (NPU) and tensor processing units (TPUs), but is not limited to the above-described examples.

The description provided with reference to FIGS. 1 through 16 also applies to the description of FIG. 17, and thus a detailed description will be omitted for conciseness.

FIG. 18 illustrates an example electronic device including a battery state estimation apparatus according to one or more embodiments.

Referring to FIG. 18, in a non-limiting example, an electronic device 1800 may include the battery 110 and the battery state estimation apparatus 120.

The electronic device 1800 may be applied to a vehicle (e.g., an electric vehicle, etc.), a mobile device (e.g., a smartphone, a tablet personal computer (PC), etc.), and the like.

In an example, the electronic device 1800 may perform the operations of the battery state estimation apparatus 120 described above. The electronic device 1800 may determine a voltage difference between an estimated voltage of the battery 110 determined by a battery model and a sensed voltage of the battery 110 obtained using a voltage sensor. The electronic device 1800 may determine an SOC error amount based on the determined voltage difference. The electronic device 1800 may determine a first cumulative SOC compensation amount that is accumulated SOC compensation amounts used to compensate the SOC of the battery 110 at a partially discharged point in time of the battery 110. The electronic device 1800 may estimate a second cumulative SOC compensation amount at a fully discharged point in time of the battery 110 based on the determined first cumulative SOC compensation amount and a predetermined SOC compensation amount prediction curve. The electronic device 1800 may adjust the estimated second cumulative SOC compensation amount based on the determined SOC error amount. The electronic device 1800 may update an aging parameter of the battery model based on the adjusted second cumulative SOC compensation amount.

The description provided with reference to FIGS. 1 through 17 also applies to the description of FIG. 18, and thus a detailed description will be omitted for conciseness.

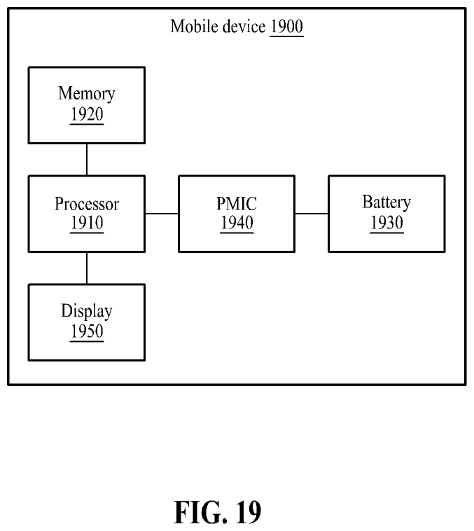

FIG. 19 illustrates an example mobile device according to one or more embodiments.

Referring to FIG. 19, in a non-limiting example, a mobile device 1900 may include a processor 1910, a memory 1920, a battery 1930, a power management integrated circuit (PMIC) 1940, and a display 1950.

The memory 1920 may include computer-readable instructions. The processor 1910 may be configured to execute computer-readable instructions, such as those stored in the memory 1920, and through execution of the computer-readable instructions, the processor 1910 is configured to perform one or more, or any combination, of the operations and/or methods described herein. The memory 1920 may be a volatile or nonvolatile memory. The memory 1920 may store a battery model.

In an example, the PMIC 1940 may charge the battery 1930 with power received from an external device (e.g., a travel adapter or a wireless charger) of the mobile device 1900. The PMIC 1940 may supply power stored in the battery 1930 to components (e.g., the processor 1910 and the like) of the mobile device 1900.

The PMIC 1940 may obtain a sensed voltage by sensing a voltage of the battery 1930 through a voltage sensor, and transfer the obtained sensed voltage to the processor 1910. In an example, although not illustrated in FIG. 19, a voltage sensor may be positioned near the battery 1930, and the voltage sensor may sense the voltage of the battery 1930 and transfer the obtained sensed voltage to the processor 1910.

The processor 1910 may perform at least some or all of the operations of the battery state estimation apparatus 120 described above.

In an example, the processor 1910 may control the display 1950 such that state information (e.g., an SOC and the like) of the battery 1930 is displayed on the display 1950.

The description provided with reference to FIGS. 1 through 18 also applies to the description of FIG. 19, and thus a detailed description will be omitted for conciseness.

The electronic devices, electronic apparatuses, processors, memories, battery state estimation apparatuses, batteries, battery system 100, battery 110, battery state estimation apparatus 120, battery model 410, compensator 420, voltage sensor 1720, processor 1710, memory 1730, electronic device 1800, mobile device 1900, processor 1910, memory 1920, battery 1930, PMIC 1940, and display 1950 described herein and disclosed herein described with respect to FIGS. 1-19 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-19 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RW, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
determining a voltage difference between an estimated voltage of a battery determined through a battery model and a sensed voltage of the battery;
determining a state of charge (SOC) error amount based on the determined voltage difference;
determining a first cumulative SOC compensation amount, the first cumulative SOC compensation amount being accumulated SOC compensation amounts used to compensate an SOC of the battery at a partially discharged point in time of the battery;
estimating a second cumulative SOC compensation amount at a fully discharged point in time of the battery based on the determined first cumulative SOC compensation amount and a predetermined SOC compensation amount prediction curve;
adjusting the estimated second cumulative SOC compensation amount based on the determined SOC error amount; and
updating an aging parameter of the battery model based on the adjusted second cumulative SOC compensation amount.

2. The method of claim 1, wherein the adjusting of the estimated second cumulative SOC compensation amount comprises:
adjusting the estimated second cumulative SOC compensation amount by subtracting the determined SOC error amount from the estimated second cumulative SOC compensation amount or adding the estimated second cumulative SOC compensation amount to the determined SOC error amount.

3. The method of claim 1, wherein the determining of the voltage difference comprises:
determining whether a start condition for determining the SOC error amount is satisfied; and
in response to determining that the start condition is satisfied, determining the voltage difference.

4. The method of claim 3, wherein the determining whether the start condition is satisfied comprises:
determining that the start condition is satisfied in response to an anode concentration of the battery reaching a predetermined concentration value or the SOC of the battery reaching a predetermined SOC value.

5. The method of claim 1, wherein the estimating of the second cumulative SOC compensation amount comprises:
obtaining a third cumulative SOC compensation amount corresponding to a partially discharged battery state at the partially discharged point in time in the SOC compensation amount prediction curve;
obtaining a fourth cumulative SOC compensation amount corresponding to a fully discharged battery state at the fully discharged point in time in the SOC compensation amount prediction curve; and
estimating the second cumulative SOC compensation amount using the determined first cumulative SOC compensation amount, the obtained third cumulative SOC compensation amount, and the obtained fourth cumulative SOC compensation amount.

6. The method of claim 1, wherein the determining of the SOC error amount comprises:
obtaining an open circuit voltage (OCV) corresponding to the SOC of the battery determined by the battery model in an OCV table; and
determining the SOC error amount by reflecting the determined voltage difference in the obtained OCV.

7. The method of claim 1, wherein the determining of the SOC error amount comprises:
determining a first open circuit potential (OCP) of each electrode of plural electrodes of the battery using a surface concentration of each of the electrodes;
determining a first OCV of the battery using each determined first OCP;
compensating each determined surface concentration based on an initial SOC error amount;
determining a second OCP of the each electrode of the plural electrodes using each compensated surface concentration;
determining a second OCV of the battery using each determined second OCP; and
determining the SOC error amount using the determined first OCV, the determined second OCV, the initial SOC error amount, and the determined voltage difference.

8. The method of claim 1, wherein the updating of the aging parameter comprises:
storing aging parameter values calculated based on the adjusted second cumulative SOC compensation amount in a memory; and
in response to an update condition for the aging parameter being satisfied, updating the aging parameter using one or more aging parameter values stored in the memory.

9. The method of claim 1, wherein the updating of the aging parameter comprises:
storing the adjusted second cumulative SOC compensation amount in a memory;
in response to an update condition for the aging parameter being satisfied, calculating an average value of a plurality of adjusted second cumulative SOC compensation amounts stored in the memory; and
updating the aging parameter using the calculated average value.

10. The method of claim 1, wherein the aging parameter comprises an electrode balance shift.

11. A processor-implemented method, the method comprising:
determining a state of charge (SOC) error amount based on a determined voltage difference between an estimated voltage of a battery determined through a battery model and a sensed voltage of the battery;
estimating a second cumulative SOC compensation amount at a fully discharged point in time of the battery based on a first cumulative SOC compensation amount, the first cumulative SOC compensation amount being accumulated SOC compensation amounts used to compensate an SOC of the battery at a partially discharged point in time of the battery, and a predetermined SOC compensation amount prediction curve; and
updating an aging parameter of the battery model based adjusting the estimated second cumulative SOC compensation amount based on the determined SOC error amount.

12. An electronic device comprising:
a processor configured to execute instructions; and
a memory storing the instructions and a battery model, wherein execution of the instructions configures the processor to:
determine a voltage difference between an estimated voltage of a battery determined through the battery model and a sensed voltage of the battery;
determine a state of charge (SOC) error amount based on the determined voltage difference;
determine a first cumulative SOC compensation amount, the first cumulative SOC compensation amount being accumulated SOC compensation amounts used to compensate an SOC of the battery at a partially discharged point in time of the battery;
estimate a second cumulative SOC compensation amount at a fully discharged point in time of the battery based on the determined first cumulative SOC compensation amount and a predetermined SOC compensation amount prediction curve;
adjust the estimated second cumulative SOC compensation amount based on the determined SOC error amount; and
update an aging parameter of the battery model based on the adjusted second cumulative SOC compensation amount.

13. The electronic device of claim 12, wherein the processor is further configured to:
adjust the estimated second cumulative SOC compensation amount by subtracting the determined SOC error amount from the estimated second cumulative SOC compensation amount or adding the estimated second cumulative SOC compensation amount to the determined SOC error amount.

14. The electronic device of claim 12, wherein the processor is further configured to:
determine whether a start condition for determining the SOC error amount is satisfied; and
in response to determining that the start condition is satisfied, determine the voltage difference.

15. The electronic device of claim 14, wherein the processor is further configured to determine that the start condition is satisfied in response to an anode concentration of the battery reaching a predetermined concentration value or the SOC of the battery reaching a predetermined SOC value.

16. The electronic device of claim 12, wherein the processor is further configured to:
obtain a third cumulative SOC compensation amount corresponding to a particularly discharged battery state at the partially discharged point in time in the SOC compensation amount prediction curve;
obtain a fourth cumulative SOC compensation amount corresponding to a fully discharged battery state at the fully discharged point in time in the SOC compensation amount prediction curve; and
estimate the second cumulative SOC compensation amount using the determined first cumulative SOC compensation amount, the obtained third cumulative SOC compensation amount, and the obtained fourth cumulative SOC compensation amount.

17. The electronic device of claim 12, wherein the processor is configured to:
obtain an open circuit voltage (OCV) corresponding to the SOC of the battery determined by the battery model in an OCV table; and
determine the SOC error amount by reflecting the determined voltage difference in the obtained OCV.

18. The electronic device of claim 12, wherein the processor is configured to:
determine a first open circuit potential (OCP) of each electrode of plural electrodes of the battery using a surface concentration of each of the electrodes;
determine a first OCV of the battery using each determined first OCP;
compensate each determined surface concentration based on an initial SOC error amount;
determine a second OCP of the each electrode of the plural electrodes using each compensated surface concentration;
determine a second OCV of the battery using each determined second OCP; and
determine the SOC error amount using the determined first OCV, the determined second OCV, the initial SOC error amount, and the determined voltage difference.

19. The electronic device of claim 12, wherein the processor is configured to:
store aging parameter values calculated based on the adjusted second cumulative SOC compensation amount in the memory; and
in response to an update condition for the aging parameter being satisfied, update the aging parameter using one or more aging parameter values stored in the memory.

20. The electronic device of claim 12, wherein the processor is configured to:
store the adjusted second cumulative SOC compensation amount in the memory;
in response to an update condition for the aging parameter being satisfied, calculate an average value of a plurality of adjusted second cumulative SOC compensation amounts stored in the memory; and
update the aging parameter using the calculated average value.
